(19) United States
(12) Patent Application Publication
(10) Pub. No.: US 2005/0273826 A1
(43) Pub. Date: Dec. 8, 2005

(54) Information playback method

(75) Inventor: Hirokazu Sakane, Osaka (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD.

(21) Appl. No.: 11/135,306

(22) Filed: May 24, 2005

(30) Foreign Application Priority Data
Jun. 3, 2004 (JP) 2004-165740

(51) Int. Cl. H04N 7/173; H03G 3/20

(52) U.S. Cl. 725/89; 725/100; 725/131; 381/110

(57) ABSTRACT

In response to a request for read of image information from a recording medium on which non-multiplexed voice information and image information have been recorded, for example, whether or not a sufficient amount of voice information to prevent occurrence of underflow has been stored in a buffer memory is first determined. If it is determined that the amount of voice information in the buffer memory is not sufficient (less than a predetermined amount), read of image information is not started immediately, but voice information is read until the amount becomes equal to or more than the predetermined amount, and then read of image information is started. This enables simultaneous playback of voice information and image information without voice interruption.

### CROSS-REFERENCE TO RELATED APPLICATIONS

This non-provisional application claims priority under 35 U.S.C. §119(a) on Patent Application No. 2004-165740 filed in Japan on Jun. 3, 2004, the entire contents of which are hereby incorporated by reference.

### BACKGROUND OF THE INVENTION

The present invention relates to an information playback method for reading voice information and image information from a recording medium, such as an optical disk, on which voice information like MP3 and image information like JPEG have been recorded, to play back voice and images.

Playback of information recorded on an optical disk will be described.

FIG. 1 shows an optical disk playback apparatus. In FIG. 1, the solid-line arrows represent flows of data and dotted-line arrows represent flows of control signals. An optical disk 1, such as a CD-R, is a recording medium on which image information and voice information have been recorded. The playback apparatus includes an optical pickup 2, a servo section 3, a digital signal processor 4, a buffer memory 5, an audio decoder 6, a video decoder 7 and a CPU 12. The optical pickup 2 is composed of a laser source, a photo detector and the like. The servo section 3 controls drive of the optical pickup 2 and also supplies a playback signal read from the optical disk 1 by the optical pickup 2 to the digital signal processor 4. The digital signal processor 4 carries out EFM demodulation, error correction and the like for the playback signal supplied from the servo section 3. The buffer memory 5 stores data processed by the digital signal processor 4. The audio decoder 6 decodes voice information supplied from the buffer memory 5 to a buffer 8 in the audio decoder 6 and outputs the results as an audio signal 10. The video decoder 7 decodes image information supplied from the buffer memory 5 to a buffer 9 in the video decoder 7 and outputs the results as a video signal 11. The CPU 12 controls the servo section 3, the digital signal processor 4, the buffer memory 5, the audio decoder 6, the video decoder 7 and the like. A playback apparatus like that described above is disclosed in Japanese Laid-Open Patent Publication No. 6-111495, for example.

In playback of voice and images using the playback apparatus described above, information to be played back is read from the optical disk 1, and the read information is subjected to digital signal processing and then stored in the buffer memory 5. Thereafter, voice information is supplied to the audio decoder 6 while image information is supplied to the video decoder 7, to be played back as an audio signal and a video signal. If information read from the optical disk 1 is logically continuous information including multiplexed voice information and image information, like an MPEG program stream, the read data can be supplied to the audio decoder 6 and the video decoder 7 sequentially according to management information in a file, to thereby enable voice playback and image playback.

However, in the conventional information playback method described above, voice playback free from interruption will not be attained in the case of playing back non-multiplexed voice information and image information, such as voice information like MP3 and image information like JPEG, simultaneously.

Simultaneous playback of voice information and image information as described above will be described with reference to FIGS. 2 to 4. FIG. 2 shows an example of optical disk like a CD-R having voice information and image information recorded thereon. Referring to FIG. 2, the optical disk 1 has a region 14 on which voice information like MP3 has been recorded, a region 15 on which image information like JPEG has been recorded, and the regions other than the regions 14 and 15, denoted by 13.

FIG. 3 is a graph showing changes in voice information amount over time, in which the y-axis represents the data amount and the x-axis represents the time. Lines 16 and 17 respectively represent the amounts of voice information stored in the buffer memory 5 and the audio decoder inner buffer 8. During playback of voice information read from the optical disk 1 as shown in FIG. 2, voice information is stored in the buffer memory 5 as shown by the line 16 in FIG. 3. The voice information amount 16 in the buffer memory 5 increases with the passage of time until the buffer memory 5 becomes full at time TB. The buffer memory 5 is then kept in the full state in which stop and restart of read of voice information from the optical disk 1 are repeated. Also, the voice information stored in the buffer memory 5 is sequentially supplied to the audio decoder 6, and thus the voice information amount 17 in the audio decoder inner buffer 8 also increases with the passage of time. The audio decoder inner buffer 8 becomes full at time TA, and then is kept in the full state in which stop and restart of supply of voice information to the audio decoder inner buffer 8 are repeated.

FIG. 4 is a graph showing changes in image information amount over time, in which the y-axis represents the data amount and the x-axis represents the time. Lines 18 and 19 respectively represent the amounts of image information stored in the buffer memory 5 and the video decoder inner buffer 9. Assume that image playback is started at TC. At this time, the CPU 12 controls to stop the read of voice information and then start read of image information from the optical disk 1. To start read of image information from the optical disk 1, it is necessary to move the optical pickup 2 and carry out digital signal processing. Therefore, image information starts to be stored in the buffer memory 5 only at time TF, a given time after the time TC, as shown in FIG. 4, and the image information amount 18 in the buffer memory 5 increases with the passage of time. At and after the time TC at which the read of voice information was stopped, the voice information amount 16 in the buffer memory 5 decreases with the passage of time, and finally falls in an underflow state at time TD. At and after the time TD, the voice information amount 17 in the audio decoder inner buffer 8 also decreases with the passage of time, and finally falls in an underflow state at time TE. At and after the time TE, no voice is played back.

As described above, in the case of executing image playback during the progress of voice playback, interruption-free voice playback will not be attained unless the image playback is terminated before voice information in the audio decoder inner buffer 8 underflows.

### SUMMARY OF THE INVENTION

An object of the present invention is providing an information playback method that permits playback of voice without interruption and also playback of images at high speed even in simultaneous playback of voice information and image information included in a logically continuous information unit in a non-multiplexed state, like MP3 and JPEG.

To attain the object described above, according to the present invention, a set value of voice information amount that must be held in a buffer memory or in an audio decoder inner buffer to prevent occurrence of underflow in the memory or the buffer is determined. If the voice information amount is below the set value, higher priority is given to read of voice information from a recording medium to the buffer memory or supply of voice information from the buffer memory to an audio decoder than image information processing, to thereby prevent interruption during voice playback.

The information playback method of the present invention is an information playback method for reading voice information and image information from a recording medium to a buffer memory, the voice information and the image information being recorded in the recording medium in a non-multiplexed state, supplying the read voice information to a buffer in an audio decoder and the read image information to a buffer in a video decoder, and generating an audio signal in the audio decoder and a video signal in the video decoder, to enable playback of voice and images, the method including the steps of: stopping read of voice information from the recording medium to the buffer memory only when the voice information amount in the buffer memory is equal to or more than a predetermined amount that is large enough to prevent occurrence of underflow in the buffer memory, in the case of attempting simultaneous read of voice information and image information from the recording medium to the buffer memory; and starting read of voice information from the recording medium to the buffer memory, subsequent to stopping read of image information from the recording medium to the buffer memory, only when the voice information amount in the buffer memory becomes less than the predetermined amount due to supply of voice information from the buffer memory to the audio decoder inner buffer after the step of stopping read of voice information.

Alternatively, the information playback method of the present invention is an information playback method for reading voice information and image information from a recording medium to a buffer memory, the voice information and the image information being recorded in the recording medium in a non-multiplexed state, supplying the read voice information to a buffer in an audio decoder and the read image information to a buffer in a video decoder, and generating an audio signal in the audio decoder and a video signal in the video decoder, to enable playback of voice and images, the method includes the steps of: stopping read of voice information from the recording medium to the buffer memory only when the voice information amount in the buffer memory is equal to or more than a predetermined amount that is large enough to prevent occurrence of underflow in the buffer memory, in the case of attempting simultaneous read of voice information and image information from the recording medium to the buffer memory; and starting read of voice information from the recording medium to the buffer memory, subsequent to stopping read of image information from the recording medium to the buffer memory, only when the voice information amount in the buffer memory becomes less than a second predetermined amount that is smaller than the predetermined amount and is large enough to prevent occurrence of underflow due to supply of voice information from the buffer memory to the audio decoder inner buffer after the step of stopping read of voice information.

In one embodiment of the invention, the processing of supplying the read voice information from the buffer memory to the audio decoder inner buffer includes the steps of: computing the free space of the audio decoder inner buffer; and supplying voice information of an amount smaller than the free space computed in the step of computing the free space of the audio decoder inner buffer, from the buffer memory to the audio decoder inner buffer, and the processing of supplying the read image information from the buffer memory to the video decoder inner buffer includes the steps of: computing the free space of the video decoder inner buffer; and supplying image information of an amount smaller than the free space computed in the step of computing the free space of the video decoder inner buffer, from the buffer memory to the video decoder inner buffer.

In another embodiment of the invention, the processing of supplying the read image information from the buffer memory to the video decoder inner buffer is executed only when the voice information amount in the audio decoder inner buffer is equal to or more than a predetermined amount that is large enough to prevent occurrence of underflow.

In yet another embodiment of the invention, the processing of supplying the read image information from the buffer memory to the video decoder inner buffer includes the steps of: computing the free space of the video decoder inner buffer; and supplying image information from the buffer memory to the video decoder inner buffer only when the free space of the video decoder inner buffer computed in the step of computing the free space of the video decoder inner buffer is larger than a predetermined image information transfer unit.

In yet another embodiment of the invention, the step of starting read of voice information includes the steps of: acquiring a voice information transfer rate at which voice information is transferred from the buffer memory to the audio decoder inner buffer; computing the voice information read pre-start time required from the time of stop of read of image information from the recording medium to the buffer memory until the time of start of read of voice information from the recording medium to the buffer memory; computing the minimum voice information amount supplied from the buffer memory to the audio decoder inner buffer during the read pre-start time based on the voice information transfer rate and the read pre-start time; and restarting read of voice information from the recording medium to the buffer memory only when the voice information amount in the buffer memory is smaller than the minimum voice information amount.

In yet another embodiment of the invention, the processing of reading image information from the recording medium to the buffer memory includes reading in advance next image information from the recording medium to the buffer memory after termination of current image playback in the case of repeating image playback, and the processing of supplying image information from the buffer memory to the video decoder inner buffer includes supplying the next image information read in advance from the buffer memory to the video decoder inner buffer when start of next image playback is requested.

Alternatively, the information playback method of the present invention is an information playback method for reading voice information and image information from a recording medium to a buffer memory, the voice information and the image information being recorded in the recording medium in a non-multiplexed state, supplying the read voice information to a buffer in an audio decoder and the read image information to a buffer in a video decoder, and generating an audio signal in the audio decoder and a video signal in the video decoder, to enable playback of voice and images, the method including the steps of: stopping read of voice information from the recording medium to the buffer memory only when the voice information amount in the audio decoder inner buffer is equal to or more than a predetermined amount that is large enough to prevent occurrence of underflow in the audio decoder inner buffer, in the case of attempting simultaneous read of voice information and image information from the recording medium to the buffer memory; and starting read of voice information from the recording medium to the buffer memory, subsequent to stopping read of image information from the recording medium to the buffer memory, only when the voice information amount in the audio decoder inner buffer becomes less than a second predetermined amount that is smaller than the predetermined amount and large enough to prevent occurrence of underflow in the audio decoder inner buffer due to playback of voice after the step of stopping read of voice information.

Alternatively, the information playback method of the present invention is an information playback method for reading voice information and image information from a recording medium to a buffer memory, the voice information and the image information being recorded in the recording medium in a non-multiplexed state, supplying the read voice information to a buffer in an audio decoder and the read image information to a buffer in a video decoder, and generating an audio signal in the audio decoder and a video signal in the video decoder, to enable playback of voice and images, the method including the steps of: stopping read of voice information from the recording medium to the buffer memory only when the voice information amount in the buffer memory exceeds the free space of the audio decoder inner buffer, in the case of attempting simultaneous read of voice information and image information from the recording medium to the buffer memory; and starting read of voice information from the recording medium to the buffer memory, subsequent to stopping read of image information from the recording medium to the buffer memory, only when the image information amount in the buffer memory exceeds the free space of the video decoder inner buffer or when the voice information amount in the audio decoder inner buffer becomes less than a predetermined amount that is large enough to prevent occurrence of underflow due to playback of voice after the step of stopping read of voice information.

In one embodiment, the method further includes the steps of: acquiring the voice information amount in the buffer memory; flushing the voice information in the buffer memory; acquiring the voice information amount in the audio decoder inner buffer; flushing the voice information in the audio decoder inner buffer; acquiring an address on the recording medium of voice information currently being read at the flushing of the voice information in the audio decoder inner buffer; computing an address on the recording medium of voice information currently being played back based on the acquired address on the recording medium of the voice information currently being read, the acquired voice information amount in the buffer memory and the acquired voice information amount in the audio decoder inner buffer; and restarting read of voice information from the address on the recording medium of the voice information currently being played back computed in the step of computing an address.

As described above, according to the present invention, image information is read only when a predetermined amount of voice information large enough to prevent occurrence of underflow has been stored in the buffer memory. Hence, occurrence of underflow can be avoided, and thus voice can be played back without interruption while images are being played back.

According to the present invention, read of voice information is stopped to start read of image information when a sufficient amount of voice information has been stored in the buffer memory. Once the voice information amount in the buffer memory becomes less than a second predetermined amount that is close to the level causing underflow, the read of image information is stopped to restart read of voice information. This increases the duration of read of image information. Hence, voice can be played back without interruption while images are being played back. Also, the image information read efficiency enhances, and thus images can be played back at higher speed.

In some playback apparatuses, during supply of information to one of the video decoder and the audio decoder, supply of information to the other decoder is not allowed.

In such apparatuses, if the state of waiting for completion of supply of image information to the video decoder lasts long, voice information will not be supplied to the audio decoder during the waiting time even if a sufficient amount of voice information exists in the buffer memory, and thus the voice information amount in the audio decoder inner buffer may cause underflow. In the information playback method of the present invention, voice information and image information are respectively supplied by amounts corresponding to the free spaces of the buffers in the audio and video decoders. Therefore, the buffer of each decoder is prevented from overflowing, and it is unnecessary to wait for completion of supply of information from the buffer memory. Hence, voice can be played back without interruption while images are being played back.

According to the present invention, image information is supplied to the video decoder only when voice information of an amount large enough to prevent occurrence of underflow is held in the audio decoder inner buffer. Hence, voice can be played back without interruption while images are being played back.

In some playback apparatuses, during supply of information to one of the video decoder and the audio decoder, supply of information to the other decoder is not allowed. In such apparatuses, if the voice information amount in the video decoder inner buffer becomes close to the level causing underflow during supply of image information to the video decoder, it is necessary to stop the supply of image information to the video decoder and start supply of voice information to the audio decoder to prevent voice interruption. In the information playback method of the present invention, image information is supplied in information transfer units even if a larger space is available in the video decoder. This shortens the duration of one time of supply of image information to the video decoder, and thus enables immediate switching to supply of voice information to the audio decoder. Hence, voice can be played back without interruption while images are being played back.

In general, in reading information recorded on an optical disk, the time of travel of the optical pickup from the current position to the target position and the time for digital signal processing such as demodulation and error correction are required. The time of travel of the optical pickup can be computed from the difference between the distances of the current position and the target position from the disk center. The amount of voice information in the buffer memory consumed per unit time relates to the transfer rate of voice information. In the information playback method of the present invention, a fixed amount is set as the minimum voice information amount with which occurrence of underflow of voice information can be prevented, that is, as the voice information amount in the buffer memory at the time point at which read of image information is stopped to restart read of voice information. In other words, a fixed amount is not computed from the maximum travel time (for example, the time of travel from an innermost position to an outermost position) of the optical pickup or the maximum transfer rate (for example, the MP3 maximum transfer rate), for example, but is computed as the minimum voice information amount from the transfer rate of voice information currently being played back and the travel time of the optical pickup from the current read position to the target read position. Therefore, a further smaller amount can be set as the minimum voice information amount with which occurrence of underflow of voice information can be prevented, and thus a longer duration can be set for reading image information. Hence, voice can be played back without interruption while images are being played back. Also, with enhanced read efficiency, images can be played back at further high speed.

According to the present invention, in a slide show of playing back images repeatedly at predetermined intervals, for example, image information is read in advance and supply of image information to the video decoder is started at a request of start of image playback. Hence, images can be played back at higher speed.

According to the present invention, information read from a recording medium to the buffer memory is switched between voice information and image information according to the voice information amount in the audio decoder inner buffer, and the read information is sequentially supplied to the corresponding audio decoder or video decoder. Hence, even in playback of voice during the progress of image playback, read of information to the buffer memory and supply of information to a decoder can be facilitated.

According to the present invention, information read from a recording medium to the buffer memory is switched between voice information and image information according to the voice information amount in the audio decoder inner buffer, the free space of the audio decoder inner buffer and the free space in the video decoder inner buffer, and the read information is sequentially supplied to the corresponding audio decoder or video decoder. Hence, even in playback of voice during the progress of image playback, read of information to the buffer memory and supply of information to a decoder can be facilitated.

According to the present invention, in flushing of voice information in the audio decoder inner buffer, the address on the recording medium of voice information currently being played back is computed based on the address on the recording medium of voice information currently being read, the voice information amount in the buffer memory and the voice information amount in the audio decoder inner buffer, and read of voice information is restarted from the computed address. Hence, occurrence of a voice dropout can be prevented.

### BRIEF DESCRIPTION OF THE DRAWINGS

FIG. 1 is a block diagram of an optical disk playback apparatus.

FIG. 2 is a view showing an optical disk on which voice information and image information have been recorded separately.

FIG. 3 is a view showing changes in voice information amount over time in a buffer memory and an audio decoder inner buffer.

FIG. 4 is a view showing changes in image information amount over time in the buffer memory and a video decoder inner buffer.

FIG. 5 is a flowchart of playback of voice and images in an information playback method of Embodiment 1 of the present invention.

FIG. 6 is a flowchart of image playback request execution processing in the information playback method of Embodiment 1.

FIG. 7 is a flowchart of voice playback request execution processing in the information playback method of Embodiment 1.

FIG. 8 is a flowchart of read information switch processing in the information playback method of Embodiment 1.

FIG. 9 is a flowchart of read information switch processing in an information playback method of Embodiment 2 of the present invention.

FIG. 10 is a flowchart of voice information supply processing in an information playback method of Embodiment 3 of the present invention.

FIG. 11 is a flowchart of image information supply processing in the information playback method of Embodiment 3.

FIG. 12 is a flowchart of playback of voice and images in an information playback method of Embodiment 4 of the present invention.

FIG. 13 is a flowchart of processing of supplying information to a decoder in the information playback method of Embodiment 4.

FIG. 14 is a flowchart of processing of supplying information to a decoder in an information playback method of Embodiment 5 of the present invention.

FIG. 15 is a flowchart of read information switch processing in an information playback method of Embodiment 6 of the present invention.

FIG. 16 is a flowchart of playback of voice and images in an information playback method of Embodiment 7 of the present invention.

FIG. 17 is a flowchart of processing of supplying information to a decoder in the information playback method of Embodiment 7.

FIG. 18 is a flowchart of image playback request execution processing in an information playback method of Embodiment 8 of the present invention.

FIG. 19 is a flowchart of voice playback request execution processing in the information playback method of Embodiment 8.

FIG. 20 is a flowchart of read information switch processing in the information playback method of Embodiment 8.

FIG. 21 is a flowchart of processing of supplying information to a decoder in the information playback method of Embodiment 8.

FIG. 22 is a flowchart of image playback request execution processing in an information playback method of Embodiment 9 of the present invention.

FIG. 23 is a flowchart of voice playback request execution processing in the information playback method of Embodiment 9.

FIG. 24 is a flowchart of read information switch processing in the information playback method of Embodiment 9.

FIG. 25 is a flowchart of buffer flush processing in an information playback method of Embodiment 10 of the present invention.

### DESCRIPTION OF THE PREFERRED EMBODIMENTS

Hereinafter, preferred embodiments of the present invention will be described with reference to the accompanying drawings.

### Embodiment 1

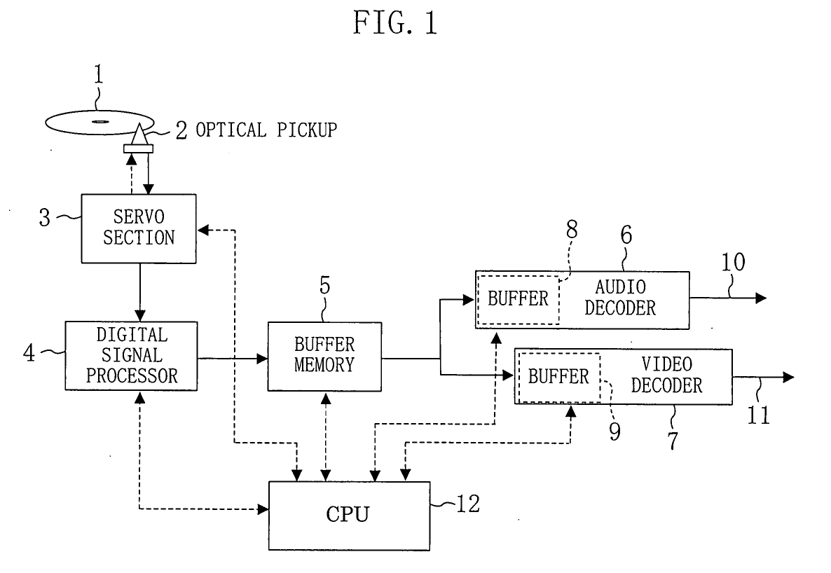

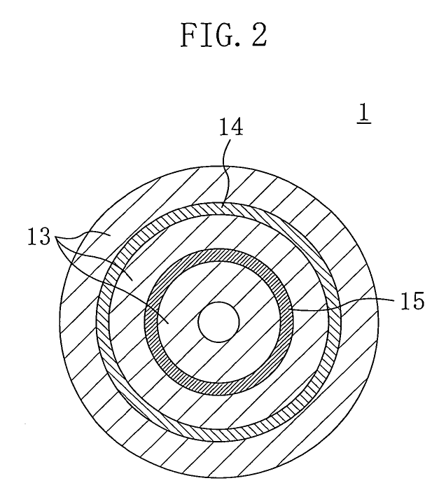

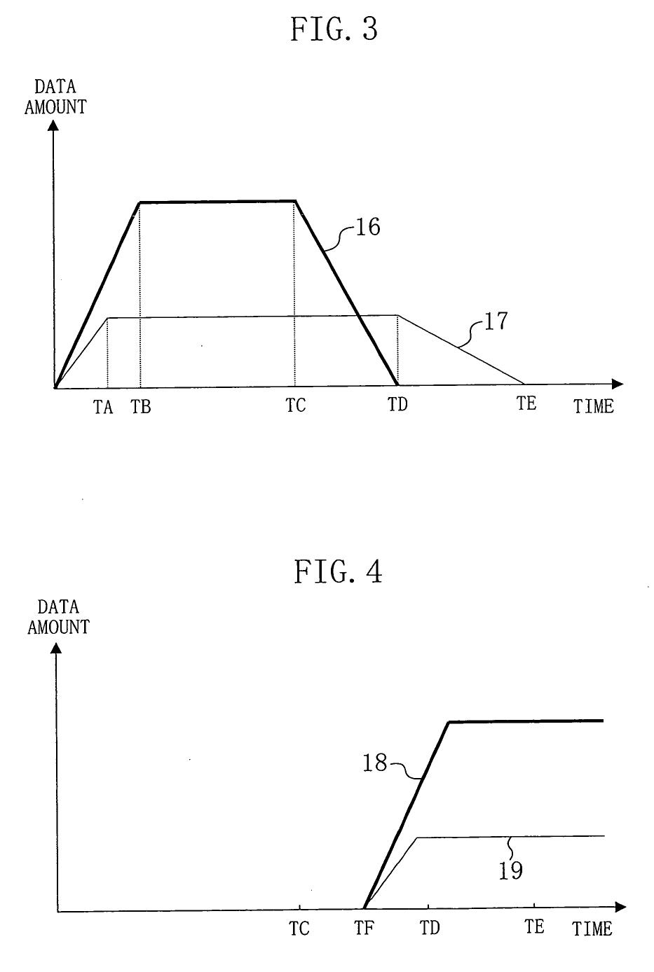

First, an optical disk playback apparatus will be described with reference to FIG. 1. In FIG. 1, the solid-line arrows represent flows of data and dotted-line arrows represent flows of control signals. An optical disk 1, such as a CD-R, is a recording medium on which image information and voice information have been recorded. An optical pickup 2 is composed of a laser source, a photo detector and the like. A servo section 3 controls drive of the optical pickup 2 and also supplies a playback signal read from the CD-R 1 by the optical pickup 2 to a digital signal processor 4. The digital signal processor 4 carries out EFM demodulation and error correction for the playback signal supplied from the servo section 3. A buffer memory 5 stores data of voice information and image information read from the optical disk 1 by the optical pickup 2 and processed by the digital signal processor 4. An audio decoder 6 decodes voice information supplied from the buffer memory 5 to a buffer 8 in the audio decoder 6 and outputs the results as an audio signal 10. A video decoder 7 decodes image information supplied from the buffer memory 5 to a buffer 9 in the video decoder 7 and outputs the results as a video signal 11. A CPU 12 controls the servo section 3, the digital signal processor 4, the buffer memory 5, the audio decoder 6, the video decoder 7 and the like.

The information playback method of this embodiment to be discussed hereinafter is adopted for an information playback apparatus like the optical disk playback apparatus illustrated in FIG. 1.

The information playback method of Embodiment 1 of the present invention will be described.

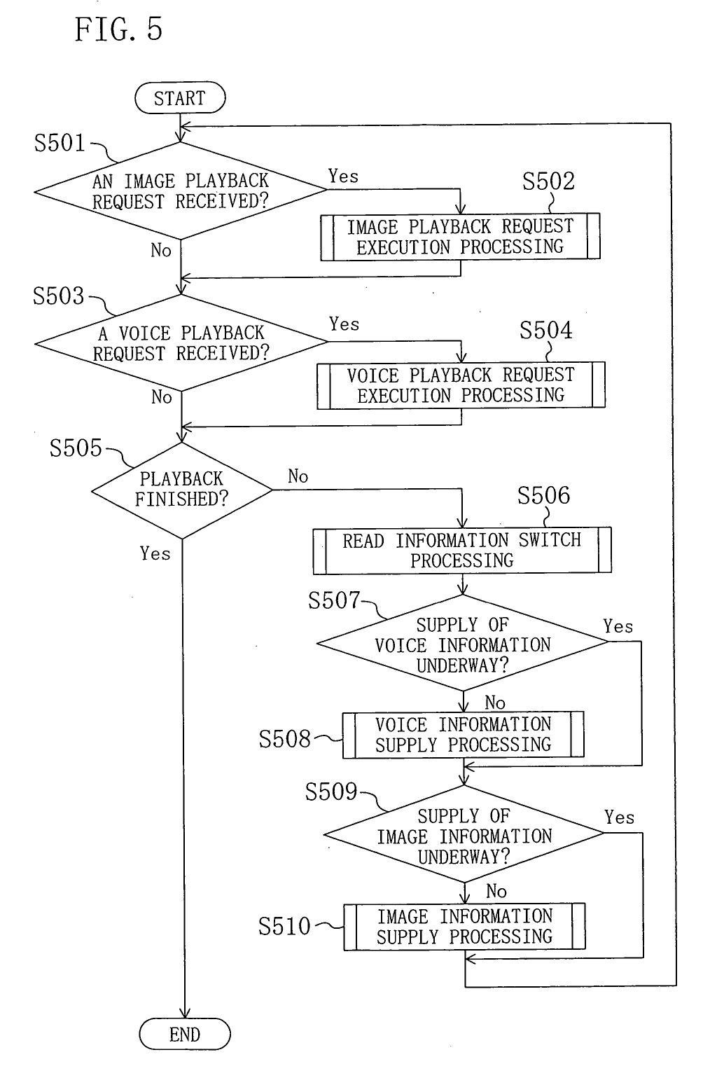

FIG. 5 is a flowchart of playback of voice and images in the information playback method of this embodiment. First, in step S501, whether or not there is an image playback request is determined. If there is an image playback request (Yes), playback of the requested image information is started in step S502 for image playback request execution processing. If there is no image playback request (No) in the step S501, or once the image playback request execution processing has been executed in the step S502, the process proceeds to step S503, to determine whether or not there is a voice playback request. If there is a voice playback request (Yes), playback of the requested voice information is started in step S504 for voice playback request execution processing. If there is no voice playback request (No) in the step S503, or once the voice playback request execution processing has been executed in the step S504, the process proceeds to step S505 to determine whether or not the playback should be terminated. If playback of the requested image information and voice information has been completed, or a playback end request has been received (Yes), the process is terminated. If playback should not be terminated (No), the process proceeds to step S506 for read information switch processing, to switch read information from the optical disk 1 between voice information and image information.

Subsequently, in step S507, whether or not supply of voice information from the buffer memory 5 to the audio decoder 6 is underway determined. If supply of voice information is not underway (No), voice information is supplied from the buffer memory 5 to the audio decoder 6 in step S508 for voice information supply processing. If supply of voice information is underway (Yes) in the step S507, or once the supply of voice information has been executed in the step S508, the process proceeds to step S509 to determine whether or not supply of image information from the buffer memory 5 to the video decoder 7 is underway. If supply of image information is not underway (No), image information is supplied from the buffer memory 5 to the video decoder 7 in step S510 for image information supply processing. Once the supply of image information has been executed in the step S510, or if supply of image information is underway (Yes) in the step S509, the process returns to the step S501 to determine whether or not there is an image playback request.

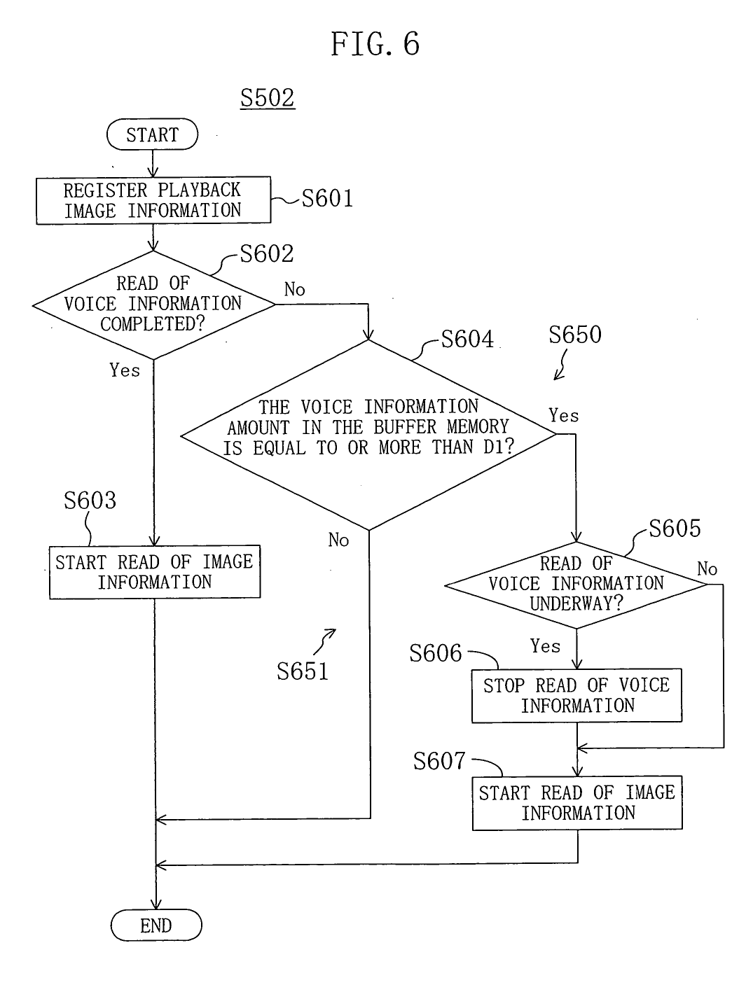

FIG. 6 is a flowchart of the image playback request execution processing in the information playback method of this embodiment, which corresponds to the processing in the step S502 in FIG. 5.

In the image playback request execution processing, first, in step S601, information required for image playback, such as the playback start address on the optical disk 1 and the playback information amount for the playback-requested image information, is acquired and registered. Thereafter, in step S602, whether or not read of voice information has been completed is determined. If all of requested voice information has been read (Yes), read of image information from the optical disk 1 to the buffer memory 5 is started in step S603. If read of all of requested voice information has not been completed (No), whether or not the voice information amount in the buffer memory 5 is equal to or more than a predetermined information amount D1 that is large enough to prevent occurrence of underflow in the buffer memory 5 is determined in step S604. If the voice information amount is less than D1 (No), voice information must be read. Accordingly, the image playback request execution processing is immediately terminated. If the voice information amount is equal to or more than D1 (Yes) in the step S604, whether or not read of voice information is underway is determined in step S605. If voice information is being read from the optical disk 1 to the buffer memory 5 (Yes) in the step S605, this read of voice information is stopped in step S606 judging that voice information has been sufficiently stored. Subsequently, in step S607, read of image information from the optical disk 1 to the buffer memory 5 is started. If read of voice information is not underway (No) in the step S605, the processing of stopping read of voice information in the step S606 is unnecessary. The process therefore directly proceeds to the step S607 to start read of image information from the optical disk 1 to the buffer memory 5.

The steps S604 and S606 described above constitute the first voice information read stop step S650, in which read of voice information from the optical disk (recording medium) 1 to the buffer memory 5 is stopped when the voice information amount in the buffer memory 5 is equal to or more than the predetermined information amount D1 that is large enough to prevent occurrence of underflow in the buffer memory 5.

The processing from the step S604 to the end of the image playback request execution processing described above constitutes first voice information read start step S651, in which read of voice information from the optical disk 1 to the buffer memory 5 is started when the voice information amount in the buffer memory 5 is less than the predetermined information amount D1.

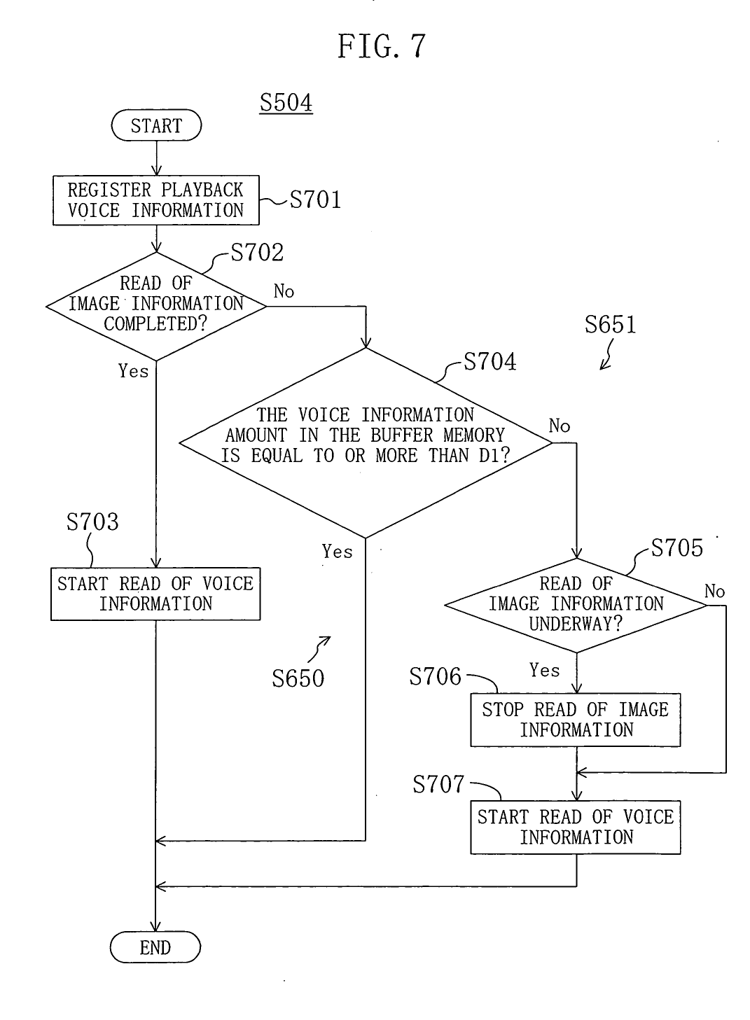

FIG. 7 is a flowchart of the voice playback request execution processing in the information playback method of this embodiment, which corresponds to the processing in the step S504 in FIG. 5.

In the voice playback request execution processing, first, in step S701, information required for voice playback, such as the playback start address on the optical disk 1 and the playback information amount for the playback-requested voice information, is acquired and registered. Thereafter, in step S702, whether or not read of image information has been completed is determined. If all of requested image information has been read (Yes), read of voice information from the optical disk 1 to the buffer memory 5 is started in step S703. If read of all of requested voice information has not been completed (No), whether or not the voice information amount in the buffer memory 5 is equal to or more than the predetermined information amount D1 is determined in step S704. If the voice information amount is equal to or more than D1 (Yes), the processing is terminated judging that voice information has been sufficiently stored. If the voice information amount is less than D1 (No) in the step S704, it is necessary to stop read of image information before additionally reading voice information from the optical disk 1. Therefore, in step S705, whether or not read of image information is underway is determined. If image information is being read from the optical disk 1 to the buffer memory 5 (Yes), the read of image information is stopped in step S706. Subsequently, in step S707, read of voice information from the optical disk 1 to the buffer memory 5 is started. If read of image information is not underway (No) in the step S705, the processing of stopping read of image information in the step S706 is unnecessary. The process therefore directly proceeds to the step S707, to start read of voice information from the optical disk 1 to the buffer memory 5.

The processing from the step S704 to the end of the voice playback request execution processing described above constitutes the first voice information read stop step S650, in which read of voice information from the optical disk 1 to the buffer memory 5 is stopped when the voice information amount in the buffer memory 5 is equal to or more than the predetermined information amount D1 that is large enough to prevent occurrence of underflow in the buffer memory 5.

The steps S704 and S707 described above constitute the first voice information read start step S651, in which read of voice information from the optical disk 1 to the buffer memory 5 is started when the voice information amount in the buffer memory 5 is less than the predetermined information amount D1.

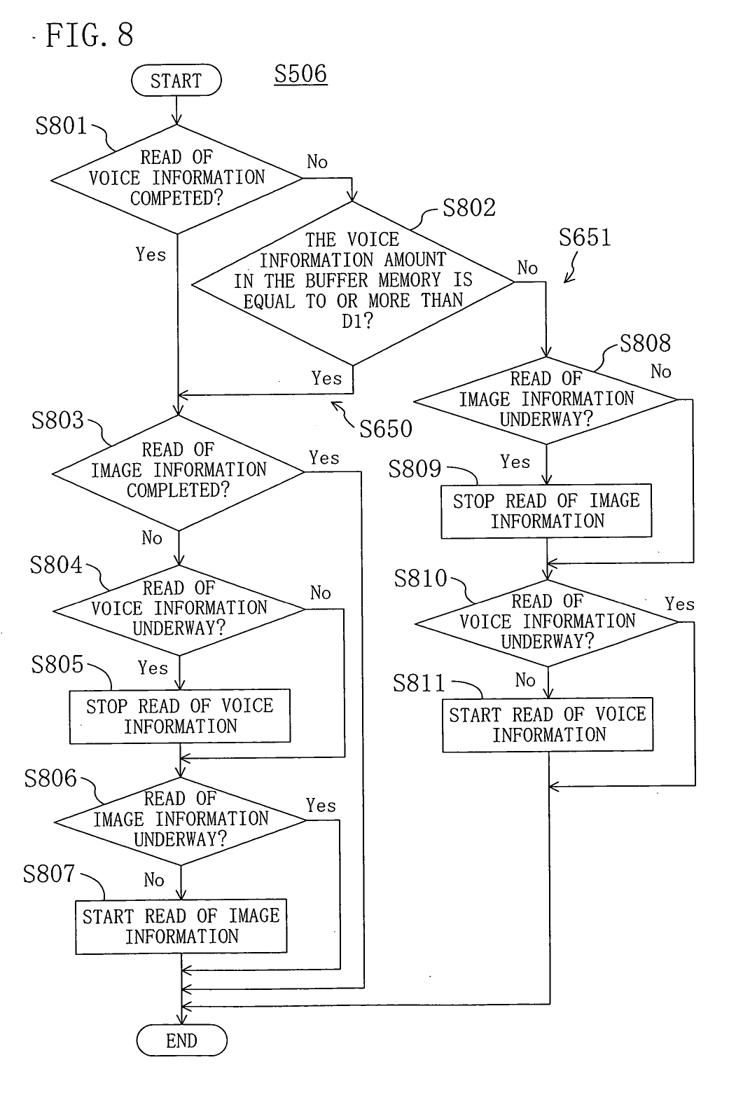

FIG. 8 is a flowchart of the read information switch processing in the information playback method of this embodiment, which corresponds to the processing in the step S506 in FIG. 5.

In the read information switch processing, first, in step S801, whether or not read of voice information has been completed is determined. If all of requested voice information has been read (Yes), whether or not read of image information has been completed is determined in step S803. If read of all of requested voice information has not been completed (No) in the step S801, whether or not the voice information amount in the buffer memory 5 is equal to or more than the predetermined information amount D1 is determined in step S802. If the voice information amount is equal to or more than D1 (Yes), the process proceeds to the step S803 to determine whether or not read of image information has been completed. If read of image information has been completed (Yes) in the step S803, the processing is terminated. If read of image information has not been completed (No), whether or not read of voice information from the optical disk 1 to the buffer memory 5 is underway is determined in step S804. If read of voice information is underway (Yes), the process proceeds to step S805 in which the read of voice information from the optical disk 1 to the buffer memory 5 is stopped. Subsequently, in step S806, whether or not read of image information is underway is determined. If read of voice information is not underway (No) in the step S804, the processing of stopping read of voice information in the step S805 is unnecessary. The process therefore directly proceeds to the step S806. If read of image information from the optical disk 1 to the buffer memory 5 is not underway (No) in the step S806, read of image information from the optical disk 1 to the buffer memory 5 is started in step S807. If read of image information is underway (Yes) in the step S806, this image read processing should just be continued. The read information switch processing is thus terminated.

If the voice information amount in the buffer memory 5 is less than the predetermined information amount D1 (No) in the step S802, voice information must be read from the optical disk 1, and thus, the process first proceeds to step S808 to determine whether or not read of image information is underway. If read of image information is underway (Yes), the read of image information is stopped in step S809, and the process proceeds to S810. If read of image information is not underway (No) in the step S808, the processing in the step S809 is unnecessary. The process therefore directly proceeds to the step S810. In the step S810, whether or not read of voice information is underway is determined. If read of voice information is not underway (No), the process proceeds to step S811 to start read of voice information, and then the read information switch processing is terminated. If read of voice information is underway (Yes) in the step S810, the read information switch processing is terminated skipping the step S811.

The step S802 and the processing down to the step S805 constitute the first voice information read stop step S650, in which read of voice information from the optical disk 1 to the buffer memory 5 is stopped when the voice information amount in the buffer memory 5 is equal to or more than the predetermined information amount D1 that is large enough to prevent occurrence of underflow in the buffer memory 5.

The step S802 and the processing down to the step S811 constitute the first voice information read start step S651, in which read of voice information from the optical disk 1 to the buffer memory 5 is started when the voice information amount in the buffer memory 5 is less than the predetermined information amount D1.

For example, in the case of executing image playback during the progress of voice playback, the voice information amount in the buffer memory 5 is first checked. If the voice information amount is less than the predetermined information amount D1, read of voice information is continued until the amount becomes equal to or more than D1, and then stopped. Thereafter, read of image information is started. If the voice information amount in the buffer memory 5 becomes less than the predetermined information amount D1 during the read of image information, the read of image information is stopped immediately to restart read of voice information.

In the case of executing voice playback during the progress of image playback, the voice information amount in the buffer memory 5 is first checked. If the voice information amount is less than the predetermined information amount D1, read of image information is stopped, to start read of voice information. Thereafter, once the voice information amount in the buffer memory 5 becomes equal to or more than the predetermined information amount D1, the read of voice information is stopped, to restart read of image information. If the voice information amount in the buffer memory 5 becomes less than the predetermined information amount D1 during the read of image information, the read of image information is stopped immediately to restart read of voice information.

By following the procedure described above, at least a fixed amount of voice information can be secured in the buffer memory 5 at all times even when image playback is done during the progress of voice playback. This can prevent occurrence of buffer underflow that will otherwise cause voice interruption.

As described above, image information is read only when the amount of voice information stored in the buffer memory 5 is large enough to prevent occurrence of underflow, and thereby, voice can be played back without interruption while images are being played back.

### Embodiment 2

An information playback method of Embodiment 2 of the present invention will be described.

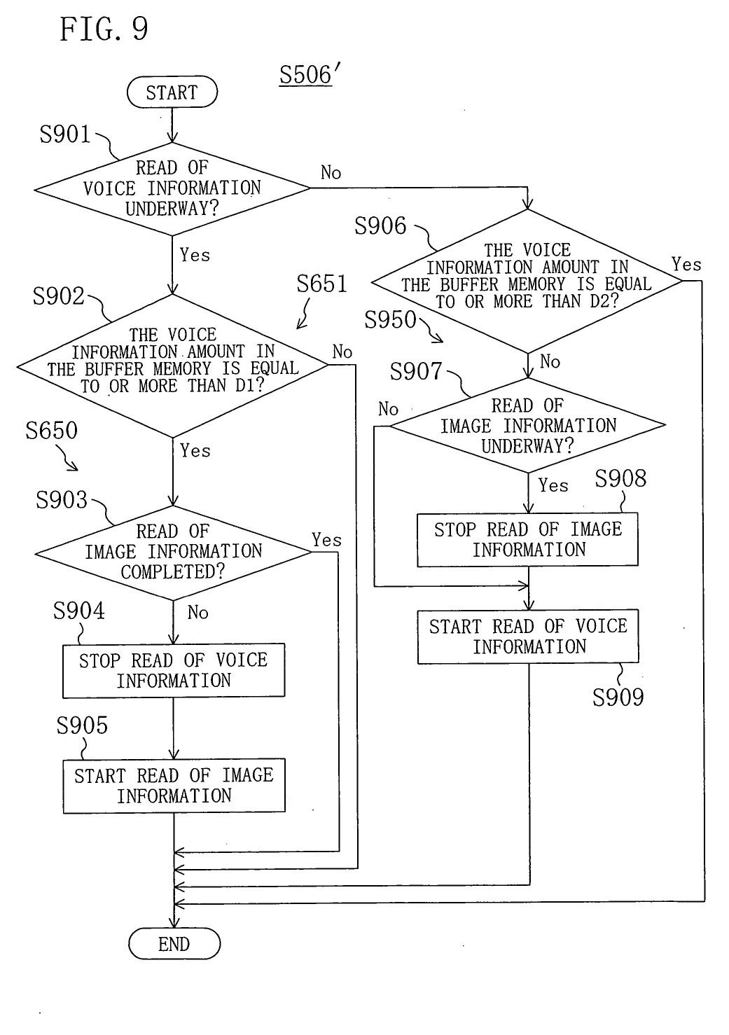

FIG. 9 is a flowchart of read information switch processing in step S506′ in the information playback method of this embodiment, which is different from the read information switch processing in Embodiment 1 shown in FIG. 8.

In the read information switch processing in this embodiment shown in FIG. 9, first, in step S901, whether or not read of voice information from the optical disk 1 to the buffer memory 5 is underway is determined. If read of voice information is underway (Yes), whether or not the voice information amount in the buffer memory 5 is equal to or more than a predetermined information amount D1 is determined in step S902. If the voice information amount is less than D1 (No) in the step S902, the read of voice information must be continued, and thus the read information switch processing is terminated. If the voice information amount is equal to or more than D1 (Yes), the process proceeds to step S903 to determine whether or not read of image information has been completed. If read of image information has been completed (Yes) in the step S903, the processing is terminated. If read of image information has not been completed (No), the process proceeds to step S904 to stop the read of voice information. Once the read of voice information is stopped, read of image information is started in step S905, and then the read information switch processing is terminated.

In the step S901, if read of voice information is not underway (No), the process proceeds to step S906, to determine whether or not the voice information amount in the buffer memory 5 is equal to or more than a second predetermined information amount D2 that is large enough to prevent occurrence of underflow in the buffer memory 5 and smaller than the predetermined information amount D1. If the voice information amount is equal to or more than D2 (Yes), the processing is terminated. If the voice information amount is less than D2 (No), the process proceeds to step S907, to determine whether or not read of image information is underway. If read of image information is underway (Yes), the read of image information is stopped in step S908. Subsequently, read of voice information is started in step S909, and then the processing is terminated.

If read of image information is not underway (No) in the step S907, the process proceeds to the step S909, skipping the step S908 of stopping read of image information, to start read of voice information. The read information switch processing in this embodiment is then terminated.

The steps S902 and S904 constitute the first voice information read stop step S650, in which read of voice information from the optical disk 1 to the buffer memory 5 is stopped when the voice information amount in the buffer memory 5 is equal to or more than the predetermined information amount D1 that is large enough to prevent occurrence of underflow in the buffer memory 5.

The processing from the step S902 to the end of the read information switch processing described above constitutes the first voice information read start step S651, in which read of voice information from the optical disk 1 to the buffer memory 5 is started when the voice information amount in the buffer memory 5 is less than the predetermined information amount D1.

Also, the steps S906 and S909 constitute second voice information read start step S950, in which read of voice information from the optical disk 1 to the buffer memory 5 is started when the voice information amount in the buffer memory 5 is less than the second predetermined information amount D2 that is less than the predetermined information amount D1 and also large enough to prevent occurrence of underflow in the buffer memory 5.

As described above, in this embodiment, in the case of executing image playback during the progress of voice playback, the voice information amount in the buffer memory 5 is checked. If the voice information amount is less than the first predetermined information amount D1, read of voice information is continued until the amount becomes equal to or more than D1 and then stopped. Thereafter, read of image information is started. If the voice information amount in the buffer memory 5 becomes less than the second predetermined information amount D2 (D2<D1) during the read of image information, the read of image information is stopped immediately to restart read of voice information.

In the case of executing voice playback during the progress of image playback, the voice information amount in the buffer memory 5 is checked. If the voice information amount is less than the first predetermined information amount D1, read of image information is stopped, to start read of voice information. Thereafter, once the voice information amount in the buffer memory 5 becomes equal to or more than the predetermined information amount D1, the read of voice information is stopped, to restart read of image information. If the voice information amount in the buffer memory 5 becomes less than the second predetermined information amount D2 (D2<D1) during the read of image information, the read of image information is stopped immediately to restart read of voice information.

Thus, read of image information is started when the voice information amount in the buffer memory 5 is equal to or more than the first predetermined information amount D1, and is stopped when the voice information amount in the buffer memory 5 becomes less than the second predetermined information amount D2 that is smaller than the first predetermined information amount D 1, to start read of voice information. This can prevent occurrence of buffer underflow that will otherwise cause voice interruption. Also, since image information is read until the voice information amount in the buffer memory 5 becomes the second predetermined information amount D2 that is smaller than the first predetermined information amount D1, the duration of read of image information can be set longer. In read of information from the optical disk 1, the optical pickup 2 travels to the read position on the optical disk 1, and during the travel of the optical pickup 2, no read of information is available. Therefore, as the number of times of switching of read information is greater, and as the travel distance of the optical pickup 2 is longer, the read efficiency degrades. In view of this, if the duration of read of image information can be set longer, the information amount obtainable by one time of read of image information will increase, and thus the number of times of travel of the optical pickup 2 can be reduced.

As described above, image information is read only when the voice information amount stored in the buffer memory 5 is large enough to prevent occurrence of underflow, and thereby, voice can be played back without interruption while images are being played back. Also, since the duration of read of image information is set longer, the image information read efficiency enhances, and thus images can be played back at higher speed than in the information playback method of Embodiment 1.

### Embodiment 3

An information playback method of Embodiment 3 of the present invention will be described.

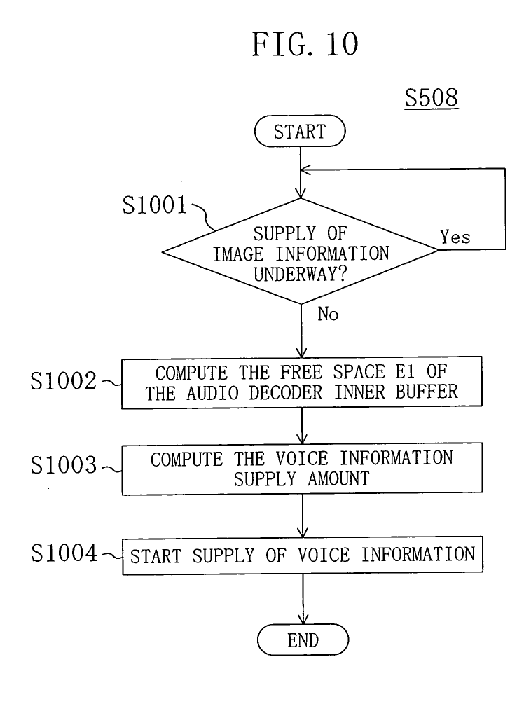

FIG. 10 is a flowchart of voice information supply processing in the information playback method of this embodiment, which corresponds to the processing in the step S508 in Embodiment 1 shown in FIG. 5.

First, in step S1001, whether or not supply of image information from the buffer memory 6 to the video decoder 7 is underway is determined. If the supply is underway (Yes), the process returns to the step S1001. If the supply is not underway (No), the process proceeds to step S1002 to compute the free space of the audio decoder inner buffer 8. Thereafter, in step S1003, a voice information supply amount that is smaller than the free space of the audio decoder inner buffer 8 computed in the step S1002 is computed. Subsequently, in step S1004, supply of voice information of the amount computed in the step S1003 from the buffer memory 5 to the audio decoder 6 is started. Once the supply of the voice information of the computed amount has been completed, the processing is terminated.

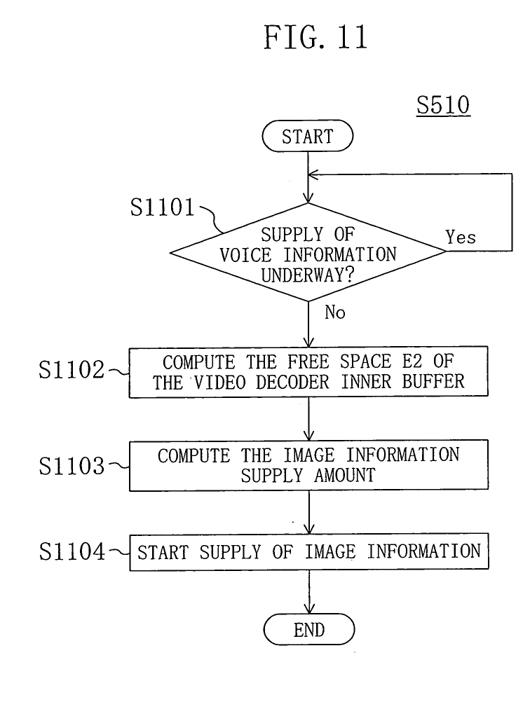

FIG. 11 is a flowchart of image information supply processing in the information playback method of this embodiment, which corresponds to the processing in the step S510 in Embodiment 1 shown in FIG. 5.

First, in step S1101, whether or not supply of voice information from the buffer memory 5 to the audio decoder 6 is underway is determined. If the supply is underway (Yes), the process returns to the step S1101. If the supply is not underway (No), the process proceeds to step S1102 to compute the free space of the video decoder inner buffer 9. Thereafter, in S1103, an image information supply amount that is smaller than the free space of the video decoder inner buffer 9 computed in the step S1102 is computed. Subsequently, in step S1104, supply of image information of the amount computed in the step S1103 from the buffer memory 5 to the video decoder 7 is started. Once the supply of image information of the computed amount has been completed, the processing is terminated.

Thus, since only an information amount corresponding to the free space of the decoder inner buffer 8 or 9 is supplied from the buffer memory 5 to the buffer 8 or 9, unnecessary waiting time for completion of information supply can be eliminated. Therefore, even in a playback apparatus that permits only supply of information from the buffer memory 5 to either the decoder 6 or 7 whichever is selected by switching, occurrence of underflow in the audio decoder inner buffer 8 that may occur during waiting for completion of supply of voice information to the video decoder 7 can be prevented.

As described above, since information is supplied only by an amount corresponding to the free space of the buffer 8 or 9 in the audio decoder 6 or the video decoder 7, it is possible to prevent occurrence of an event that the buffer 8 or 9 falls in an underflow state and waits for completion of data supply from the buffer memory 5. Thus, voice can be played back without interruption while images are being played back.

### Embodiment 4

An information playback method of Embodiment 4 of the present invention will be described.

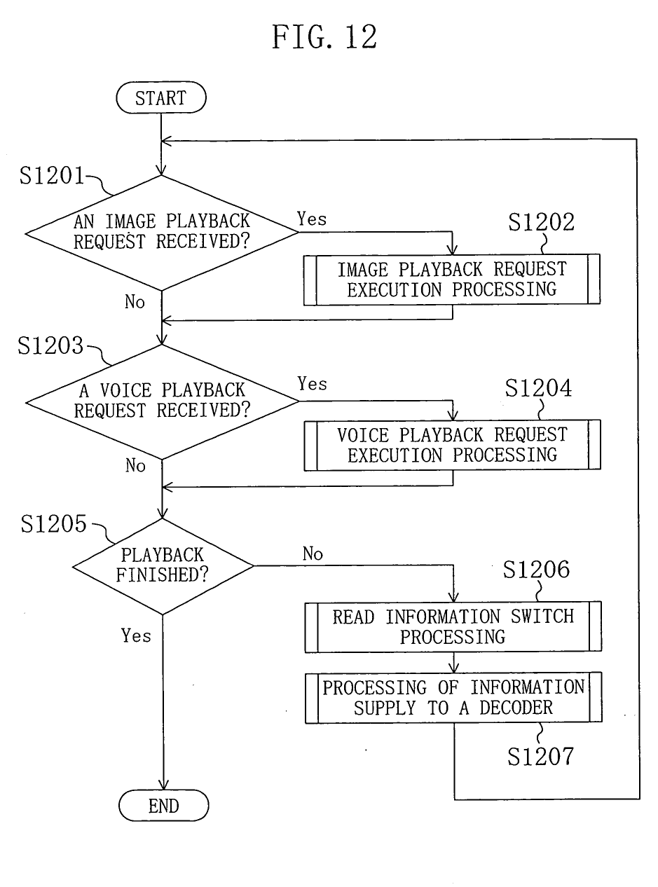

FIG. 12 is a flowchart of voice and image playback in the information playback method of this embodiment.

First, in step S1201, whether or not there is an image playback request is determined. If there is an image playback request (Yes), the process proceeds to step S1202 for image playback request execution processing, to start playback of the requested image information. If there is no image playback request (No) in the step S1201, or once the image playback request execution processing has been executed in the step S1202, the process proceeds to step S1203, to determine whether or not there is a voice playback request. If there is a voice playback request (Yes), playback of the requested voice information is started in step S1204 for voice playback request execution processing. If there is no voice playback request (No) in the step S1203, or once the voice playback request execution processing has been executed in the step S1204, the process proceeds to step S1205 to determine whether or not the playback should be finished. If playback of the requested image information and voice information has been finished, or a playback end request has been received (Yes), the process is terminated. If playback should not be terminated (No), the process proceeds to step S1206 for read information switch processing, to execute switching of read information from the optical disk 1. Subsequently, in step S1207, processing of information supply to a decoder is executed. The process then returns to the step S1201.

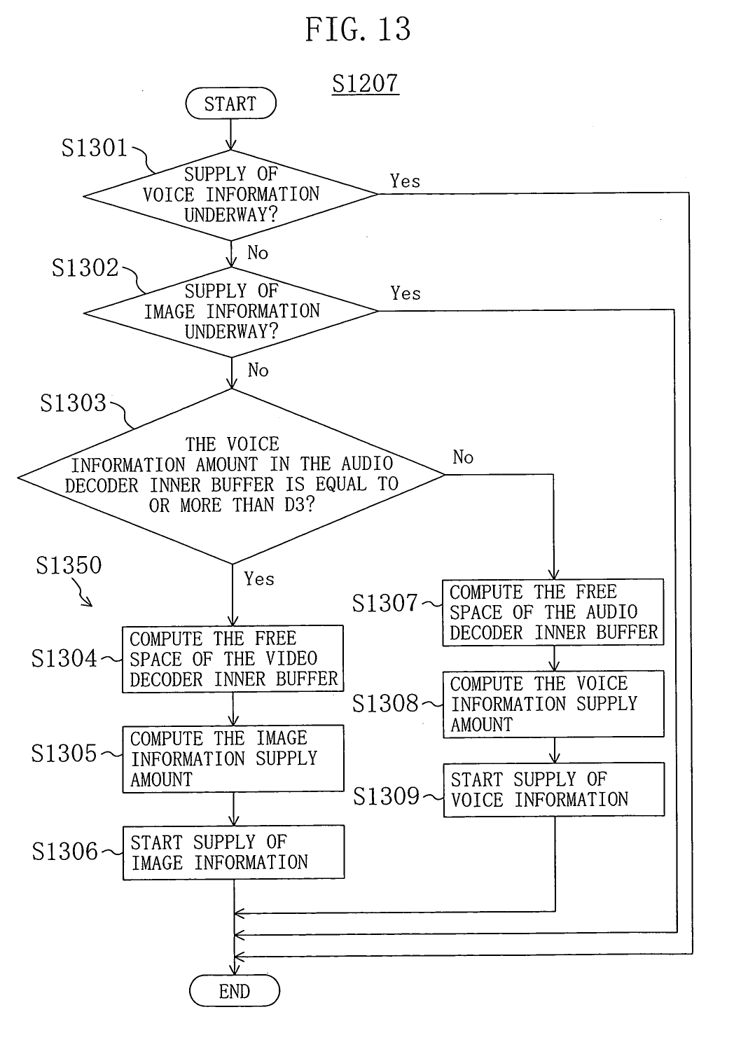

FIG. 13 is a flowchart of processing of information supply to a decoder in the information playback method of this embodiment, which corresponds to the processing in the step S1207 in FIG. 12.

First, whether or not supply of voice information from the buffer memory 5 to the audio decoder 6 is underway is determined in step S1301. If supply of voice information is underway (Yes), the processing is terminated. If supply of voice information is not underway (No), the process proceeds to step S1302, to determine whether or not supply of image information from the buffer memory 5 to the video decoder 7 is underway. If supply of image information is underway (Yes), the processing is terminated. If supply of image information is not underway (No), the process proceeds to step S1303, to determine whether or not the voice information amount in the audio decoder inner buffer 8 is equal to or more than a third predetermined information amount D3. If the voice information amount is equal to or more than the predetermined information amount D3 (Yes), the process proceeds to S1304, to compute the free space of the video decoder inner buffer 9. The process then proceeds to S1305, to compute an image information supply amount that is smaller than the free space of the video decoder inner buffer 9 computed in the step S1304. Subsequently, in step S1306, supply of image information of the amount computed in the step S1305 from the buffer memory 5 to the video decoder 7 is started. The processing of information supply to a decoder is then terminated.

If the voice information amount in the audio decoder inner buffer 8 is less than the predetermined information amount D3 (No) in the step S1303, the process proceeds to step S1307, to compute the free space of the audio decoder inner buffer 8. The process then proceeds to S1308, to compute the voice information supply amount that is smaller than the free space of the audio decoder inner buffer 8 computed in the step S1307. Subsequently, in step S1309, supply of voice information of the amount computed in the step S1308 from the buffer memory 5 to the audio decoder 6 is started. The processing of information supply to a decoder is then terminated.

The steps S1303 and S1306 constitute second image information supply step S1350, in which image information is supplied from the buffer memory 5 to the video decoder inner buffer 9 when the voice information amount in the audio decoder inner buffer 8 is equal to or more than the predetermined information amount D3 that is large enough to prevent occurrence of underflow in the audio decoder inner buffer 8.

Thus, supply of image information to the video decoder 7 is done only when the voice information amount in the audio decoder inner buffer 8 is equal to or more than the predetermined amount D3. Therefore, even in a playback apparatus that permits only supply of information from the buffer memory 5 to either the decoder 6 or 7 whichever is selected by switching, occurrence of underflow in the audio decoder inner buffer 8 can be prevented.

As described above, since image information is supplied to the video decoder 7 only when voice information of an amount large enough to prevent occurrence of underflow is held in the audio decoder inner buffer 8, voice can be played back without interruption while images are being played back.

### Embodiment 5

An information playback method of Embodiment 5 of the present invention will be described.

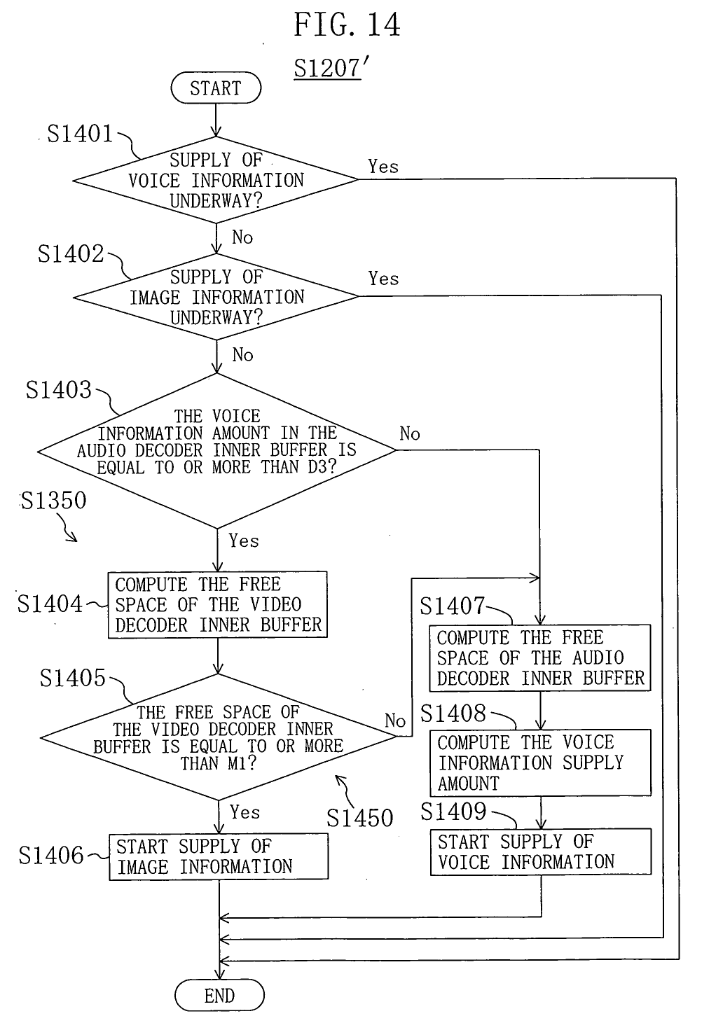

FIG. 14 is a flowchart of processing of information supply to a decoder in step S1207′ in the information playback method of this embodiment, which is different from the processing described in Embodiment 4.

First, whether or not supply of voice information from the buffer memory 5 to the audio decoder 6 is underway is determined in step S1401. If supply of voice information is underway (Yes), the processing is terminated. If supply of voice information is not underway (No), whether or not supply of image information from the buffer memory 5 to the video decoder 7 is underway is determined in step S1402. If supply of image information is underway (Yes), the processing is terminated. If supply of image information is not underway (No), whether or not the voice information amount in the audio decoder inner buffer 8 is equal to or more than a predetermined information amount D3 is determined in step S1403. If the voice information amount is equal to or more than the predetermined information amount D3 (Yes), image information is to be supplied from the buffer memory 5 to the video decoder inner buffer 9. In step S1404, therefore, the free space of the video decoder inner buffer 9 is first computed. The process then proceeds to step S1405, to determine whether or not the free space of the video decoder inner buffer 9 is equal to or more than a predetermined amount M1. If the free space computed in the step S1404 is equal to or more than the predetermined amount M1 (a predetermined image information transfer unit) (Yes), supply of image information is started in step S1406, and then the processing of information supply to the video decoder inner buffer 9 is terminated. The series of steps S1405 and S1406 constitute first image information supply step S1450.

If the voice information amount in the audio decoder inner buffer 8 is less than the predetermined information amount D3 (No) in the step S1403, or if the free space of the video decoder inner buffer 9 is less than the predetermined amount M1 (No) in the step S1405, the process proceeds to step S1407, to compute the free space of the audio decoder inner buffer 8. The process then proceeds to S1408, to compute a voice information supply amount that is smaller than the free space of the audio decoder inner buffer 8 computed in the step S1407. Subsequently, in step S1409, supply of voice information of the amount computed in the step S1408 from the buffer memory 5 to the audio decoder 6 is started, and then the processing of information supply to a decoder is terminated.

The steps S1403 and S1406 constitute the second image information supply step S1350, in which image information is supplied from the buffer memory 5 to the video decoder inner buffer 9 when the voice information amount in the audio decoder inner buffer 8 is equal to or more than the third predetermined information amount D3 that is large enough to prevent occurrence of underflow in the audio decoder inner buffer 8.

Thus, image information is supplied from the buffer memory 5 to the video decoder inner buffer 9 by the predetermined amount M1 (predetermined image information transfer unit) at a time even when a larger space is available in the video decoder inner buffer 9, to thereby shorten the waiting time for completion of supply of image information to the video decoder 7 and thus speed up the switching to supply of voice information to the audio decoder 6. Therefore, even in a playback apparatus that permits only supply of information from the buffer memory 5 to either the decoder 6 or 7 whichever is selected by switching, occurrence of underflow in the audio decoder inner buffer 8 can be prevented.

As described above, since the image information amount is supplied to the video decoder inner buffer 9 in transfer units even when a larger space is available in the video decoder inner buffer 9, the duration of one time of data supply to the video decoder 7 can be shortened, and thus switching to data supply to the audio decoder 6 can be made swiftly. Hence, voice can be played back without interruption while images are being played back.

### Embodiment 6

An information playback method of Embodiment 6 of the present invention will be described.

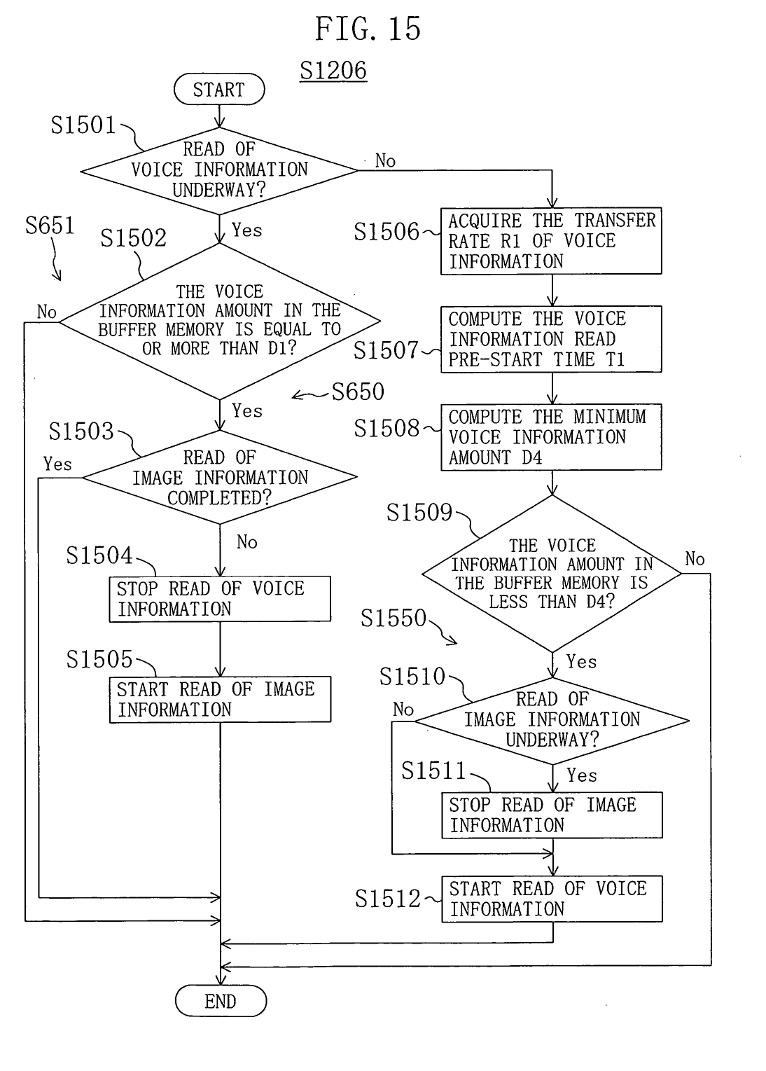

FIG. 15 is a flowchart of read information switch processing in the information playback method of this embodiment, which corresponds to the processing in the step S1206 in Embodiment 4 shown in FIG. 12.

In the read information switch processing, first, in step S1501, whether or not read of voice information from the optical disk 1 to the buffer memory 5 is underway is determined. If read of voice information is underway (Yes), the process proceeds to step S1502, in which whether or not the voice information amount in the buffer memory 5 is equal to or more than a predetermined information amount D1 is determined. If the voice information amount is less than D1 (No), the processing is terminated. If the voice information amount is equal to or more than D1 (Yes), the process proceeds to step S1503 to determine whether or not read of image information has been completed. If read of the requested image information has been completed (Yes), the read information switch processing is terminated. If read of the requested image information has not been completed (No), the process proceeds to step S1504, to stop the read of voice information from the optical disk 1 to the buffer memory 5. Subsequently, in step S1505, read of image information from the optical disk 1 to the buffer memory 5 is started, and then the read information switch processing is terminated.

If read of voice information is not underway (No) in the step S1501, the process proceeds to step S1506, to acquire the transfer rate R1 at which voice information is transferred from the buffer memory 5 to the audio decoder inner buffer 8. Subsequently, in step S1507, the voice information read pre-start time T1 required until start of read of voice information to the buffer memory 5, that is, the time period from the time point of stop of read of image information until the time point of start of read of voice information, is computed. Thereafter, in step S1508, the minimum voice information amount D4 to be supplied from the buffer memory 5 to the audio decoder inner buffer 8 during the time period from the time point of stop of read of image information until the time point of start of read of voice information is computed from the voice information transfer rate R1 acquired in the step S1506 and the voice information read pre-start time T1 computed in the step S1507. The process then proceeds to step S1509, to determine whether or not the voice information amount in the buffer memory 5 is less than the predetermined information amount D4. If the voice information amount is not less than D4 (No), the processing is terminated. If the voice information amount is less than D4 (Yes), whether or not read of image information is underway is determined in step S1510. If read of image information is underway (Yes), the read of image information from the optical disk 1 to the buffer memory 5 is stopped in step S1511, and the process proceeds to step S1512. If read of image information is not underway (No) in the step S1510, the process proceeds to the step S1512 skipping the step S1511. In the step S1512, read of voice information from the optical disk 1 to the buffer memory 5 is started (step of restarting read of voice information). Then, the read information switch processing in the case that read of voice information is not underway in the step S1501 is terminated.

The steps S1502 and S1504 constitute the first voice information read stop step S650, in which read of voice information from the optical disk 1 to the buffer memory 5 is stopped when the voice information amount in the buffer memory 5 is equal to or more than the predetermined information amount D1 that is large enough to prevent occurrence of underflow in the buffer memory 5.

The processing from the step S1502 to the end of the read information switch processing described above constitutes the first voice information read start step S651, in which read of voice information from the optical disk 1 to the buffer memory 5 is started when the voice information amount in the buffer memory 5 is less than the predetermined information amount D1.

Also, the steps S1509 and S1512 constitute third voice information read start step S1550, in which read of voice information from the optical disk 1 to the buffer memory 5 is restarted when the voice information amount in the buffer memory 5 becomes less than the minimum voice information amount D4.

In general, in reading information recorded on the optical disk 1, the time of travel of the optical pickup 2 from the current position to the target position and the time for digital signal processing such as demodulation and error correction are required. The travel time of the optical pickup 2 can be computed from the difference between the distances of the current position and the target position from the disk center. The amount of voice information in the buffer memory 5 consumed per unit time relates to the transfer rate of voice information.

For example, assuming that the transfer rate of voice information currently being decoded in the audio decoder 6 is 100 kbps, 100 kbits of voice information will be consumed per second. Assume also that image information is currently being read from the optical disk 1 to the buffer memory 5 and that one second is required to go through the processing of stopping the read of image information, traveling from the stop position to the position at which voice information to be read next is recorded on the optical disk 1, and actually reading the voice information to the buffer memory 5. In this case, to prevent occurrence of underflow of voice information in the buffer memory 5 during this one-second time period, at least 100 kbits of voice information must be stored in the buffer memory 5. In general, the transfer rate of voice information and the information read pre-start time are not constant. Therefore, the minimum amount required in the buffer memory 5 to prevent occurrence of underflow of voice information must be computed from the transfer rate and the information read pre-start time at a given time.

Thus, read of image information is started when the voice information amount in the buffer memory 5 is equal to or more than the predetermined information amount D1. When the voice information amount in the buffer memory 5 becomes less than the predetermined information amount D4 computed from the transfer rate and the information read pre-start time, the read of image information is stopped, to start read of voice information. Hence, occurrence of buffer underflow that will otherwise cause voice interruption can be prevented.

Also, since image information is read until the voice information amount in the buffer memory 5 becomes the predetermined information amount D4 that is smaller than the predetermined information amount D1, the duration of read of image information can be set longer.

The predetermined information amount D4, computed from the current transfer rate and the information read pre-start time, is the minimum voice information amount necessary to be stored in the buffer memory 5. Therefore, the time taken for the voice information amount in the buffer memory 5 to change from the predetermined information amount D1 to the predetermined information amount D4 can be maximized. In read of information from the optical disk 1, the optical pickup 2 must travel to the read position on the optical disk 1, and during the travel, no information read is available. Therefore, as the number of times of switching of read information is greater, and as the travel distance of the optical pickup 2 is longer, the read efficiency degrades. In view of this, if the duration of read of image information can be set longer, the information amount obtainable by one time of read of image information will increase, and thus the number of times of travel of the optical pickup 2 can be reduced.

As described above, image information is read only when the amount of voice information stored in the buffer memory 5 is large enough to prevent occurrence of underflow, and thereby, voice can be played back without interruption while images are being played back. Also, since the duration of read of image information is set longer, the image information read efficiency enhances, and thus images can be played back at higher speed than in the information playback methods of Embodiments 1 and 2.

### Embodiment 7

An information playback method of Embodiment 7 of the present invention will be described.

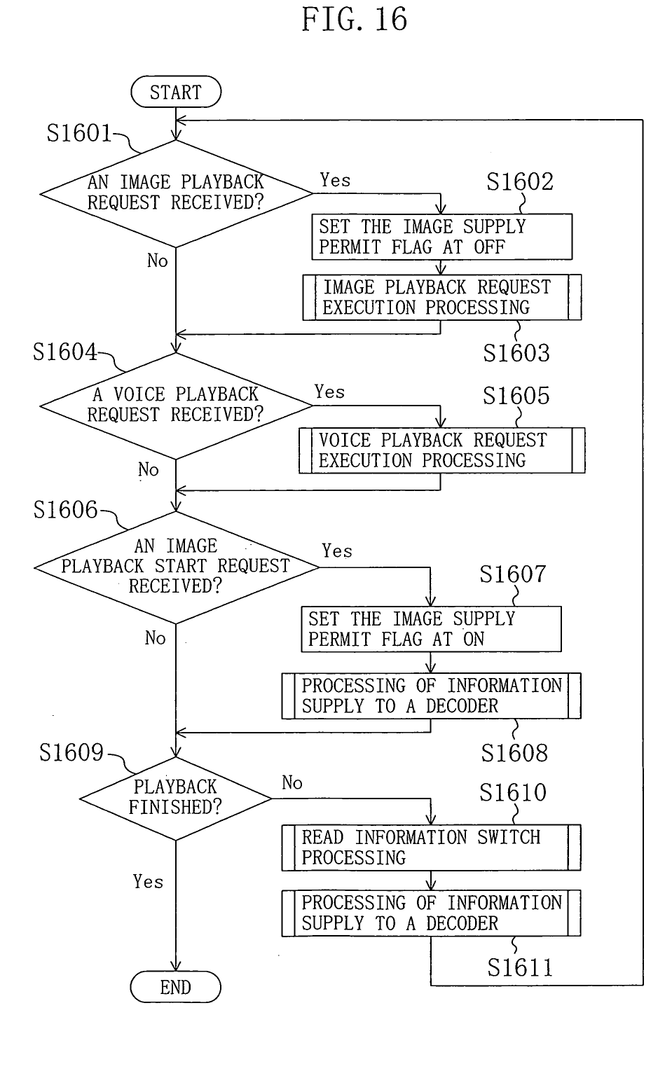

FIG. 16 is a flowchart of voice and image playback in the information playback method of this embodiment.

Referring to FIG. 16, first, in step S1601, whether or not there is an image playback request is determined. If there is an image playback request (Yes), the process proceeds to step S1602 in which an image supply permit flag is set at OFF, and then proceeds to step S1603 for image playback request execution processing (read-in-advance processing) in which playback of the requested image information is started to start storing of the image information from the optical disk 1 to the buffer memory 5, executing the read-in-advance processing of the image information. If there is no image playback request (No) in the step S1601, or once the processing in the step S1603 has been executed, the process proceeds to step S1604, to determine whether or not there is a voice playback request. If there is a voice playback request (Yes), the process proceeds to step S1605 for voice playback request execution processing in which playback of the requested voice information is started. If there is no voice playback request (No) in the step S1604, or once the processing in the step S1605 has been executed, the process proceeds to step. S1606 to determine whether or not there is an image playback start request. If there is an image playback start request (Yes), the image supply permit flag is set at ON in step S1607, and then, image supply processing is executed in step S1608 for supplying the image information read in advance in the buffer memory 5 to the buffer 8 in the video decoder. If there is no image playback start request (No) in the step S1606, or once the processing in the step S1608 has been executed, the process proceeds to step S1609, to determine whether or not playback of the requested image information or voice information has been finished, or whether or not a playback end request has been received. If playback has been finished (Yes), the processing is terminated. If playback has not been finished (No), the process proceeds to step S1610, to execute switching of read information from the optical disk 1. Subsequently, processing of information supply to a decoder is executed in step S1611. After the processing in the step S1611, the process returns to the step S1601.

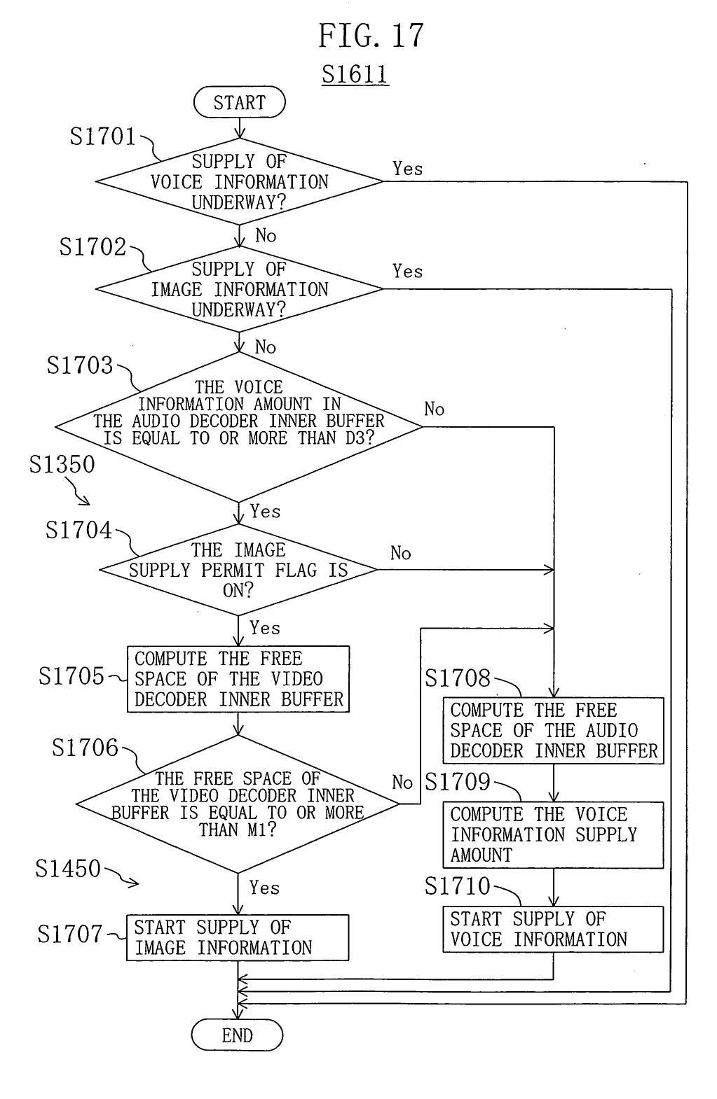

FIG. 17 is a flowchart showing details of the processing of information supply to a decoder in the step S1611 shown in FIG. 16.

Referring to FIG. 17, first, whether or not supply of voice information from the buffer memory 5 to the audio decoder 6 is underway is determined in step S1701. If supply of voice information is underway (Yes), the processing is terminated. If supply of voice information is not underway (No), whether or not supply of image information from the buffer memory 5 to the video decoder 7 is underway is determined in step S1702. If supply of image information is underway (Yes), the processing is terminated. If supply of image information is not underway (No), whether or not the voice information amount in the audio decoder inner buffer 8 is equal to or more than a predetermined information amount D3 is determined in step S1703. The series of steps 1701 through S1703 are the same as the series of steps S1401 through S1403 in Embodiment 5 shown in FIG. 14. If the voice information amount in the audio decoder inner buffer 8 is equal to or more than the predetermined information amount D3 (Yes) in the step S1403 (S1703 in this embodiment), the process proceeds to the step S1404 to compute the free space of the video decoder inner buffer 9, in Embodiment 4. In this embodiment, however, the process proceeds to step S1704 to determine whether or not the image supply permit flag is ON. If the image supply permit flag is ON (Yes) in the step S1704, the subsequent processing is the same as the processing in the steps S1404 through S1406 in Embodiment 5 shown in FIG. 14.

Specifically, in step S1705, the free space of the video decoder inner buffer 9 is computed. Subsequently, in step S1706, whether or not the free space of the video decoder inner buffer 9 is equal to or more than a predetermined amount (predetermined image information transfer unit) M1 is determined. If the free space is equal to or more than the predetermined amount M1 (Yes), the process proceeds to step S1707, to start supply of image information, and then the processing is terminated. The steps S1706 and S1707 constitute the first image information supply step S1450.

If the image supply permit flag is OFF (No) in the step S1704, which is the step unique to this embodiment distinguished from the processing in Embodiment 5 shown in FIG. 14, or if the free space of the video decoder inner buffer 9 is less than the predetermined amount M1 (No) in the step S1706, the process proceeds to step S1708 to compute the free space of the audio decoder inner buffer 8. Subsequently, in step S1709, a voice information supply amount that is less than the free space of the audio decoder inner buffer 8 computed in the step S1708 is computed. In step S1710, supply of voice information of the amount computed in the step S1709 from the buffer memory 5 to the audio decoder 6 is started, and then the processing of information supply to a decoder is terminated.

The steps S1703 and S1707 constitute the second image information supply step S1350, in which image information is supplied from the buffer memory 5 to the video decoder inner buffer 9 when the voice information amount in the audio decoder inner buffer 8 is equal to or more than the third predetermined information amount D3 that is large enough to prevent occurrence of underflow in the audio decoder inner buffer 8.

For example, in a slide show and the like in which images are played back repeatedly at predetermined intervals, a waiting time exists between playback of an image and playback of the next image. In this case, therefore, image information is read in advance from the optical disk 1 to the buffer memory 5 during the playback waiting time after playback of a given image until playback of the next image. After the lapse of a fixed time, supply of image information from the buffer memory 5 to the video decoder 7 is started.

Thus, swift image playback is attained even when voice and images are played back simultaneously.

As described above, voice can be played back without interruption while images are being played back. Also, image information is read in advance using the playback waiting time, and once an image playback start request is received, supply of image information to the video decoder 7 is started. This enables playback of images at higher speed than in the information playback methods of Embodiments 1, 2 and 6.

### Embodiment 8

An information playback method of Embodiment 8 of the present invention will be described.

The entire flowchart of voice and image playback in the information playback method of this embodiment is the same as the flowchart for the information playback method of Embodiment 4 shown in FIG. 12.

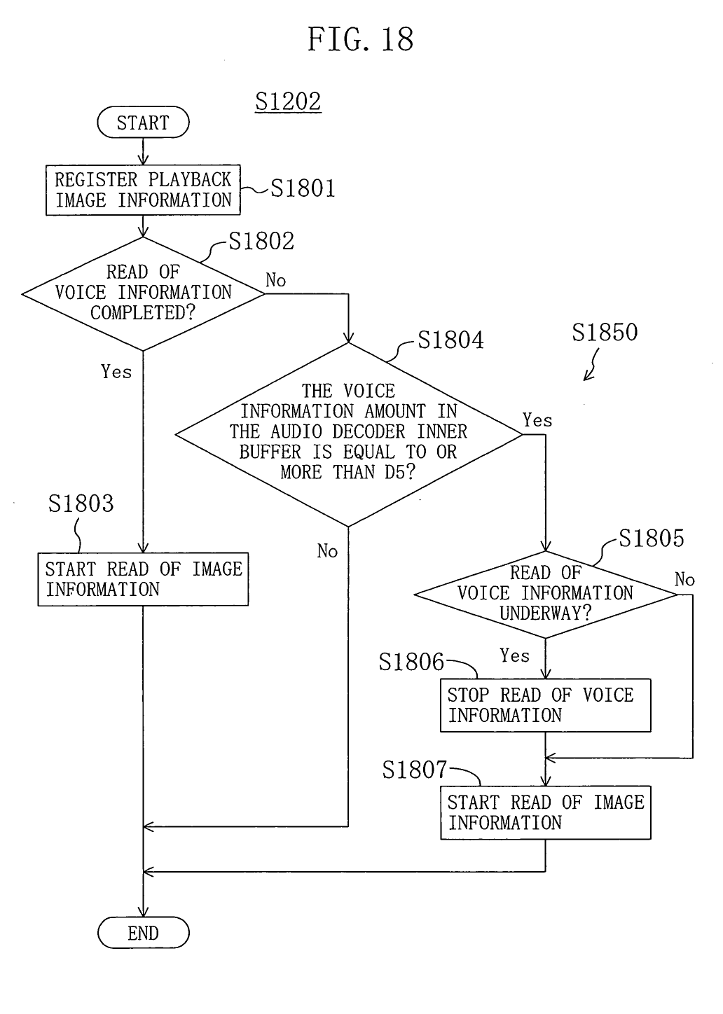

FIG. 18 is a flowchart of image playback request execution processing in the information playback method of this embodiment, which corresponds to the image playback request execution processing in the step S1202 in Embodiment 4 shown in FIG. 12.

In the image playback request execution processing shown in FIG. 18, first, in step S1801, information required for image playback, such as the playback start address on the optical disk 1 and the playback information amount for the playback-requested image information, is acquired and registered. Thereafter, in step S1802, whether or not read of voice information has been completed is determined. If all of requested voice information has been read (Yes), read of image information from the optical disk 1 to the buffer memory 5 is started in step S1803. If read of all of requested voice information has not been completed (No), whether or not the voice information amount in the audio decoder inner buffer 8 is equal to or more than a predetermined information amount D5 is determined in step S1804. If the voice information amount is less than D5 (No), the processing is terminated. If the voice information amount is equal to or more than D5 (Yes) in the step S1804, whether or not read of voice information is underway is determined in step S1805. If read of voice information from the optical disk 1 to the buffer memory 5 is underway (Yes), the read of voice information from the optical disk 1 to the buffer memory 5 is stopped in step S1806, and then read of image information from the optical disk 1 to the buffer memory 5 is started in step S1807. If read of voice information is not underway (No) in the step S1805, the process directly proceeds to the step S1807, skipping the step S1806 of stopping read of voice information, to start read of image information.

The steps S1804 and S1806 constitute voice information read stop step S1850, in which read of voice information from the optical disk 1 to the buffer memory 5 is stopped when the voice information amount in the audio decoder inner buffer 8 is equal to or more than the predetermined information amount D5 (fourth predetermined amount) that is large enough to prevent occurrence of underflow.

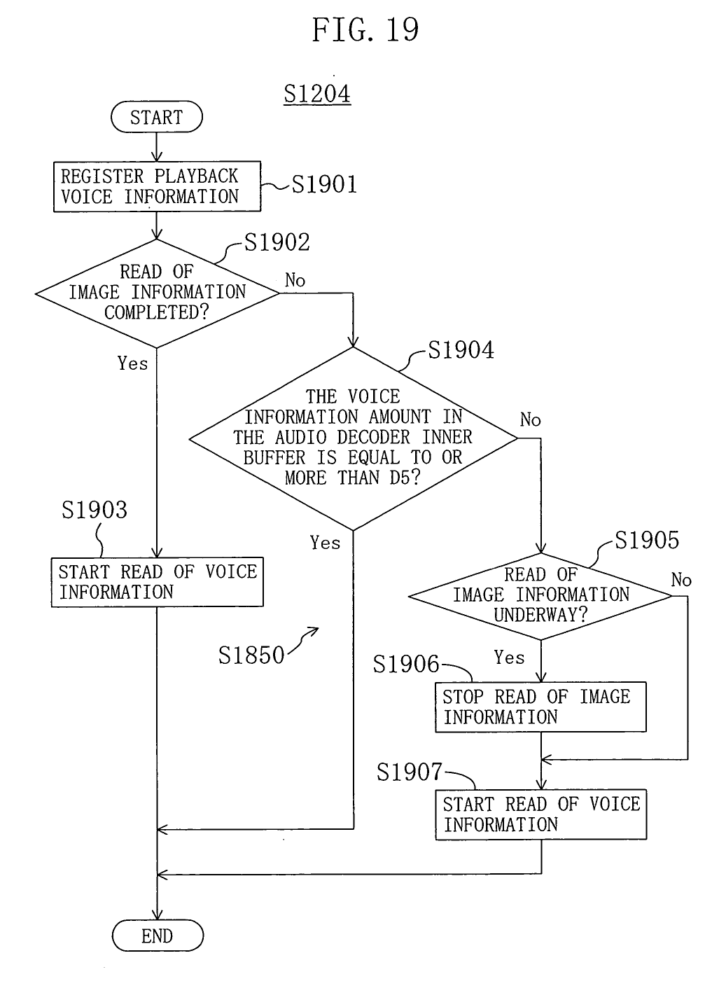

FIG. 19 is a flowchart of voice playback request execution processing in the information playback method of this embodiment, which corresponds to the voice playback request execution processing in the step S1204 in Embodiment 4 shown in FIG. 12.

In the voice playback request execution processing, first, in step S1901, information required for voice playback, such as the playback start address on the optical disk 1 and the playback information amount for the playback-requested voice information, is acquired and registered. Thereafter, in step S1902, whether or not read of image information has been completed is determined. If all of requested image information has been read (Yes), read of voice information from the optical disk 1 to the buffer memory 5 is started in step S1903. If read of all of requested voice information has not been completed (No), whether or not the voice information amount in the audio decoder inner buffer 8 is equal to or more than the predetermined information amount D5 is determined in step S1904. If the voice information amount is equal to or more than D5 (Yes), the processing is terminated. If the voice information amount is less than D5 (No) in the step S1904, the process proceeds to step S1905 to determine whether or not read of image information is underway. If read of image information from the optical disk 1 to the buffer memory 5 is underway (Yes), the read of image information from the optical disk 1 to the buffer memory 5 is stopped in step S1906, and then read of voice information from the optical disk 1 to the buffer memory 5 is started in step S1907. If read of image information is not underway (No) in the step S1905, the process directly proceeds to the step S1907, skipping the step S1906 of stopping read of image information, to start read of voice information.

The processing from the step S1904 to the end of the voice playback request execution processing described above constitutes the voice information read stop step S1850, in which read of voice information from the optical disk 1 to the buffer memory 5 is stopped when the voice information amount in the audio decoder inner buffer 8 is equal to or more than the predetermined information amount D5 that is large enough to prevent occurrence of underflow.

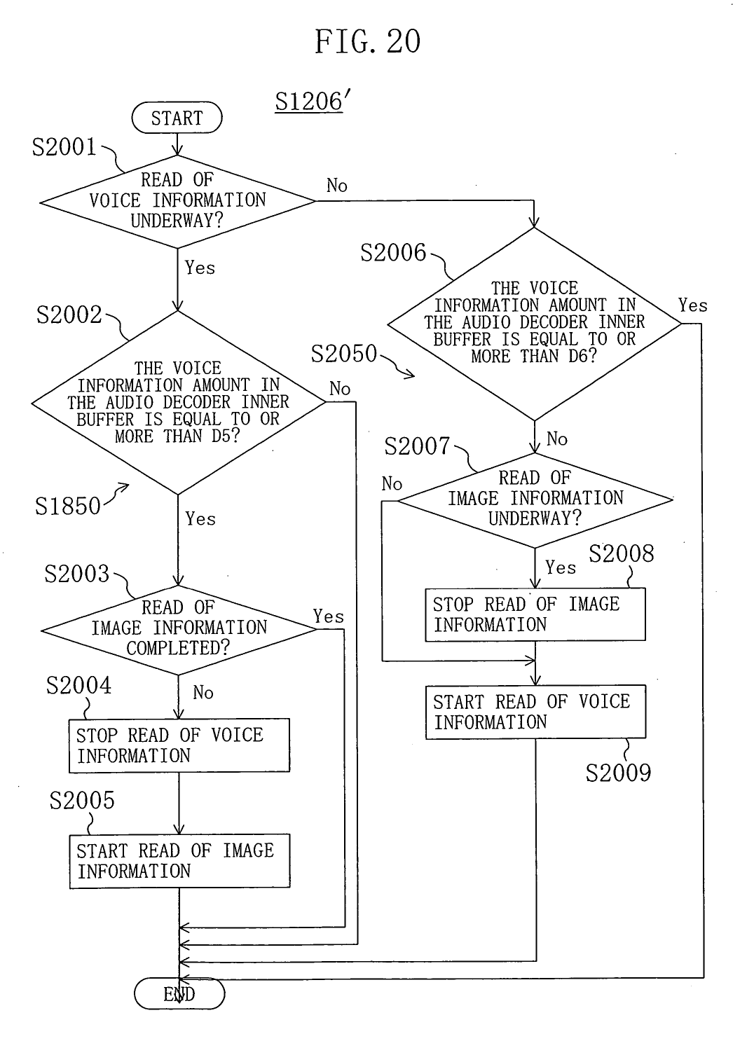

FIG. 20 is a flowchart of read information switch processing in step S1206′ in the information playback method of this embodiment, which corresponds to the read information switch processing in the step S1206 in Embodiment 4 shown in FIG. 12.

In the read information switch processing shown in FIG. 20, first, whether or not read of voice information from the optical disk 1 to the buffer memory 5 is underway is determined. If read of voice information is underway (Yes), whether or not the voice information amount in the audio decoder inner buffer 8 is equal to or more than the predetermined information amount D5 is determined in step S2002. If the voice information amount is less than D5 (No) in the step S2002, the processing is terminated. If the voice information amount is equal to or more than D5 (Yes), the process proceeds to step S2003 to determine whether or not read of image information has been completed. If read of image information has been completed (Yes), the processing is terminated. If read of image information has not been completed (No), the read of voice information is stopped in step S2004. Once the read of voice information is stopped, read of image information is started in step S2005, and then the read information switch processing is terminated.

The steps S2002 and S2004 constitute the second voice information read stop step S1850, in which read of voice information from the optical disk 1 to the buffer memory 5 is stopped when the voice information amount in the audio decoder inner buffer 8 is equal to or more than the predetermined information amount D5 that is large enough to prevent occurrence of underflow.

If read of voice information is not underway (No) in the step S2001, the process proceeds to step S2006, to determine whether or not the voice information amount in the audio decoder inner buffer 8 is equal to or more than a predetermined information amount D6 that is large enough to prevent occurrence of underflow. If the voice information amount is equal to or more than D6 (Yes), the processing is terminated. If the voice information amount is less than D6 (No), the process proceeds to step S2007, to determine whether or not read of image information is underway. If read of image information is underway (Yes), this read is stopped in step S2008, and then read of voice information is started in step S2009. The processing is then terminated.

If read of image information is not underway (No) in the step S2007, the process directly proceeds to the step S2009, skipping the step S2008 of stopping read of image information, to start read of voice information. The processing is then terminated.

The series of steps S2006 through S2009 constitute fourth voice information read start step S2050, in which read of voice information from the optical disk 1 to the buffer memory 5 is started when the voice information amount in the audio decoder inner buffer 8 is less than the predetermined information amount D6 that is smaller than the predetermined information amount D5 and large enough to prevent occurrence of underflow in the audio decoder inner buffer 8.

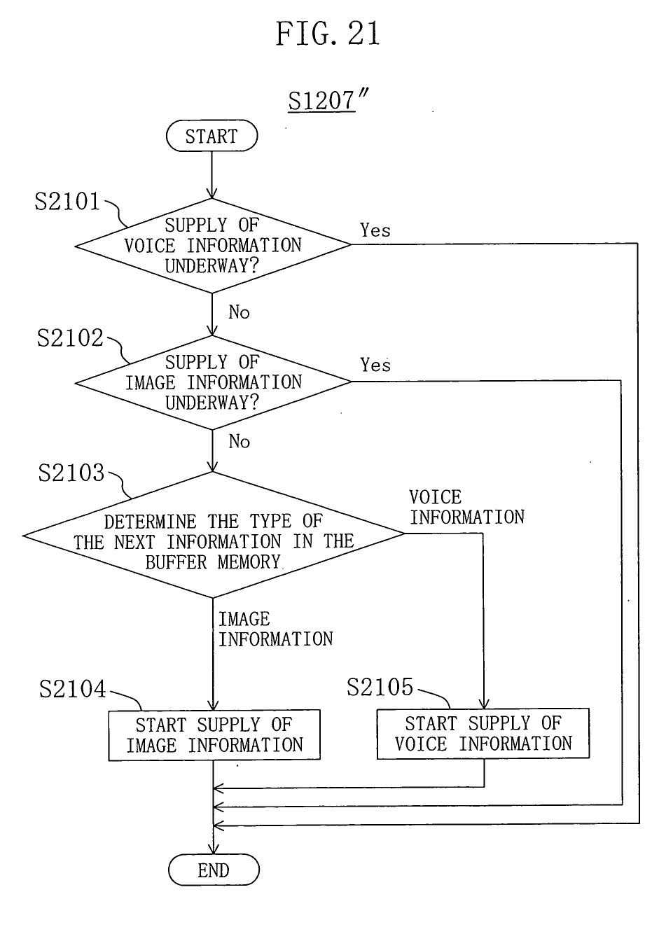

FIG. 21 is a flowchart of processing of information supply to a decoder in step S1207″ in the information playback method of this embodiment.

First, whether or not supply of voice information from the buffer memory 5 to the audio decoder 6 is underway is determined in step S2101. If supply of voice information is underway (Yes), the processing is terminated. If supply of voice information is not underway (No), the process proceeds to step S2102, to determine whether or not supply of image information from the buffer memory 5 to the video decoder 7 is underway. If supply of image information is underway (Yes), the processing is terminated. If supply of image information is not underway (No), the process proceeds to step S2103, to determine whether the type of the next information in the buffer memory 5 is image information or voice information. If it is determined that the next information in the buffer memory 5 is image information, supply of image information from the buffer memory 5 to the video decoder 7 is started in step S2104. If it is determined that the information to be supplied next is video information, supply of video information from the buffer memory 5 to the audio decoder 6 is started in step S2105. After the processing in the step S2104 or S2105, the processing of information supply to a decoder is terminated.

For example, suppose an information playback apparatus having large audio and video decoder inner buffers 8 and 9 and a small buffer memory 5. In playback of images during the progress of voice playback, the voice information amount in the audio decoder inner buffer 8 is checked. If the voice information amount is less than the predetermined information amount D5, read of voice information is stopped only after the voice information amount becomes equal to or more than the predetermined information amount D5, and then read of image information is started. If the voice information amount in the audio decoder inner buffer 8 becomes smaller than the predetermined information amount D6 (D6<D5) during the read of image information, the read of image information is immediately stopped, and read of voice information is restarted. Likewise, in playback of voice during the progress of image playback, the voice information amount in the audio decoder inner buffer 8 is checked. If the voice information amount is less than the predetermined information amount D5, read of image information is stopped and read of voice information is started. Once the voice information amount becomes equal to or more than the predetermined information amount D5, the read of voice information is stopped and read of image information is restarted. If the voice information amount in the audio decoder inner buffer 8 becomes less than the predetermined information amount D6 (D6<D5) during the read of image information, the read of image information is immediately stopped and read of voice information is restarted.

Thus, read of image information is started when the voice information amount in the audio decoder inner buffer 8 is equal to or more than the predetermined information amount D5, and is stopped when the voice information amount becomes less than the predetermined amount D6 that is smaller than the predetermined information amount D5, to restart read of voice information. This can prevent occurrence of underflow that will otherwise cause voice interruption.

Also, since read of image information is done even when the voice information amount in the audio decoder inner buffer 8 is less than the predetermined information amount D5 until it becomes less than the predetermined information amount D6, the duration of read of image information can be set longer. In read of information from the optical disk 1, the optical pickup 2 travels to the read position on the optical disk 1, and during the travel of the optical pickup 2, no information read is available. Therefore, as the number of times of switching of read information is greater, and as the travel distance of the optical pickup 2 is longer, the read efficiency degrades. In view of this, if the duration of read of image information can be set longer, the information amount obtainable by one time of read of image information will increase, and thus the number of times of travel of the optical pickup 2 can be reduced. Moreover, read of information from the optical disk 1 to the buffer memory 5 is switched according to the voice information amount in the audio decoder inner buffer 8. Therefore, information in the buffer memory 5 may simply be supplied to the audio decoder 6 or the video decoder 7 in the order of read of the information. This facilitates the supply of information from the buffer memory 5 to the decoders 6 and 7.

As described above, read of information from the optical disk 1 to the buffer memory 5 is switched according to the voice information amount in the audio decoder inner buffer 8, and the read information is sequentially supplied to the audio decoder 6 or the video decoder 7. Hence, voice can be played back without interruption while images are being played back. Also, the read of information from the optical disk 1 to the buffer memory 5 and the supply of information to the decoders 6 and 7 can be facilitated.

### Embodiment 9

An information playback method of Embodiment 9 of the present invention will be described.

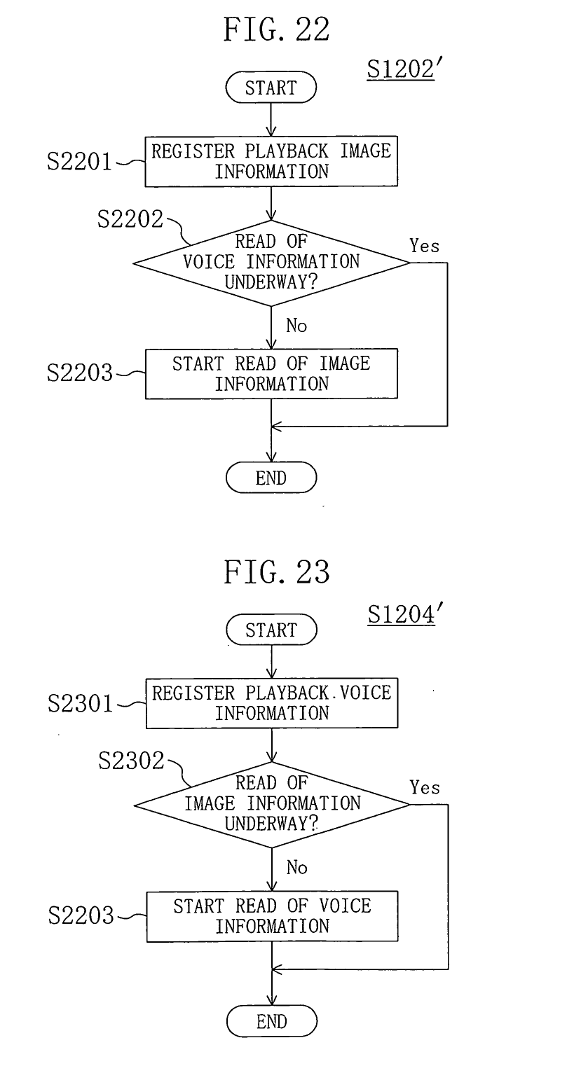

FIG. 22 is a flowchart of image playback request execution processing in step S1202′ in the information playback method of this embodiment, which corresponds to the step S1202 in Embodiment 4 shown in FIG. 12.

In the image playback request execution processing shown in FIG. 22, first, in step S2201, information required for image playback, such as the playback start address on the optical disk 1 and the playback information amount for the playback-requested image information, is acquired and registered. Thereafter, in step S2202, whether or not read of voice information from the optical disk 1 to the buffer memory 5 is underway is determined. If read of voice information is not underway (No), the process proceeds to step S2203, to start read of image information from the optical disk 1 to the buffer memory 5. If read of voice information is underway (Yes) in the step S2202, the processing is terminated skipping the step S2203.

FIG. 23 is a flowchart of voice playback request execution processing in step S1204′ in the information playback method of this embodiment, which corresponds to the step S1204 in Embodiment 4 shown in FIG. 12.

In the image playback request execution processing shown in FIG. 23, first, in step S2301, information required for voice playback, such as the playback start address on the optical disk 1 and the playback information amount for the playback-requested image information, is acquired and registered. Thereafter, in step S2302, whether or not read of image information from the optical disk 1 to the buffer memory 5 is underway is determined. If read of image information is not underway (No), the process proceeds to step S2303, to start read of voice information from the optical disk 1 to the buffer memory 5. If read of image information is underway (Yes) in the step S2302, the processing is terminated skipping the step S2203.

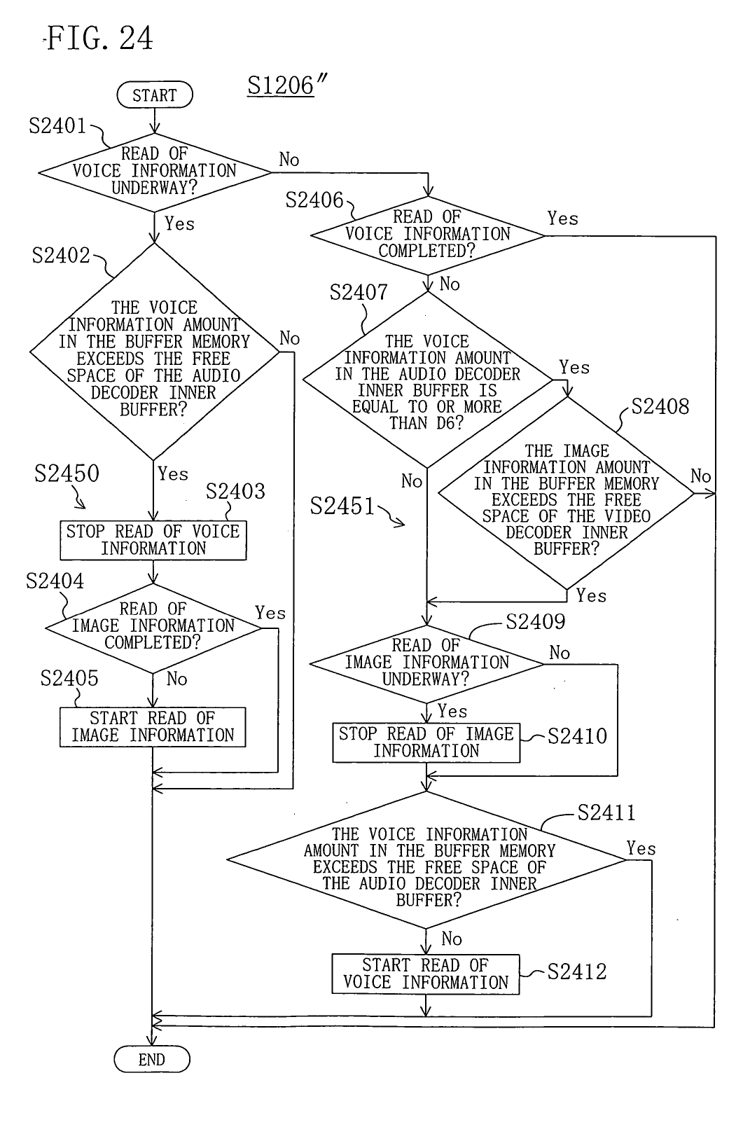

FIG. 24 is a flowchart of read information switch processing in step S1206″ in the information playback method of this embodiment, which corresponds to the processing in the step S1206 in Embodiment 4 shown in FIG. 12.

In the read information switch processing shown in FIG. 24, first, whether or not read of voice information from the optical disk 1 to the buffer memory 5 is underway is determined. If read of voice information is underway (Yes), whether or not the voice information amount in the buffer memory 5 exceeds the free space of the audio decoder inner buffer is determined in step S2402. If the voice information amount in the buffer memory 5 does not exceed the free space of the audio decoder buffer (No), the processing is terminated. If it exceeds (Yes), the read of voice information from the optical disk 1 to the buffer memory 5 is stopped in step S2403. Subsequently, in step S2404, whether or not read of image information has been completed is determined. If all of requested image information has been read (Yes), the processing is terminated. If read of all of requested image information has not been completed (No), read of image information from the optical disk 1 to the buffer memory 5 is started in step S2405, and then the processing is terminated.

The steps S2402 and S2403 constitute third voice information read stop step S2450, in which read of voice information from the optical disk 1 to the buffer memory 5 is stopped when the voice information amount in the buffer memory 5 exceeds the free space of the audio decoder inner buffer 8.

If read of voice information is not underway (No) in the step S2401, whether or not read of voice information has been completed is determined in step S2406. If read of voice information has been completed (Yes), the processing is terminated. If read of voice information has not been completed (No), whether or not the voice information amount in the audio decoder inner buffer 8 is equal to or more than a predetermined information amount D6 is determined in step S2407. If the voice information amount is equal to or more than the predetermined information amount D6 (Yes), whether or not the image information amount in the buffer memory 5 exceeds the free space of the video decoder inner buffer 9 is determined in step S2408. If the voice information amount in the buffer memory 5 does not exceed the free space of the video decoder inner buffer 9 (No), the processing is terminated. If it exceeds (Yes), or if the voice information amount is less than the predetermined amount D6 (No) in the step S2407, the process proceeds to step S2409, to determine whether or not read of image information from the optical disk 1 to the buffer memory 5 is underway. If read of image information is underway (Yes), the read of image information is stopped in step S2410, and the process proceeds to step S2411. If read of image information is not underway (No) in the step S2409, the process directly proceeds to the step S2411 skipping the step S2410. In the step S2411, whether or not the voice information amount in the buffer memory 5 exceeds the free space of the audio decoder inner buffer 8 is determined. If the voice information amount in the buffer memory 5 exceeds the free space of the audio decoder inner buffer 8 (Yes), the processing is terminated. If it does not exceed (No), read of voice information from the optical disk 1 to the buffer memory 5 is started in step S2412, and then the processing is terminated.

In FIG. 24, the steps S2407, S2408 and S2412 constitute first voice information read restart step S2451, in which read of voice information from the optical disk 1 to the buffer memory 5 is restarted when the image information amount in the buffer memory 5 exceeds the free space of the video decoder inner buffer 9 or when the voice information amount in the audio decoder inner buffer 8 is less than the predetermined information amount D6 (fifth predetermined amount).

For example, in an information playback apparatus having large audio and video decoder buffers 8 and 9 and a small buffer memory 5, it is possible to stop read of image information and switch to read of voice information before the total of the image information amount in the video decoder inner buffer 9 and the image information amount in the buffer memory 5 exceeds the buffer capacity of the video decoder 7. Therefore, even in a method of supplying information to the decoder 6 or 7 in the order of read of the information into the buffer memory 5, occurrence of underflow of voice information that may occur during waiting for completion of supply of image information can be prevented. Also, read of image information is stopped and switched to read of voice information when the voice information amount in the audio decoder inner buffer 8 becomes less than the predetermined information amount D6. Therefore, occurrence of underflow of voice information that may occur during waiting for completion of supply of image information can be prevented. Moreover, it is possible to stop read of voice information and switch to read of image information before the total of the voice information amount in the audio decoder inner buffer 8 and the voice information amount in the buffer memory 5 exceeds the buffer capacity of the audio decoder 6. Therefore, even in a method of supplying information to the decoder 6 or 7 in the order of read of the information into the buffer memory 5, occurrence of underflow of image information that may occur during waiting for completion of supply of voice information can be prevented. Hence, images can be played back at higher speed than in the information playback method of Embodiment 8, and voice can be played back without interruption.

As described above, read of information to the buffer memory 5 is switched between voice information and image information according to the voice information amount in the audio decoder inner buffer 8 and the free spaces of the audio decoder inner buffer 8 and the video decoder inner buffer 9, and the read information is supplied sequentially to the audio decoder 6 and the video decoder 7. By adopting this method, occurrence of underflow in the audio decoder inner buffer 8 and the video decoder inner buffer 9 is prevented, and thus voice can be played back without interruption while images are being played back at high speed. Also, the read of information into the buffer memory 5 and the supply of information to the decoders 6 and 7 can be facilitated.

### Embodiment 10

An information playback method of Embodiment 10 of the present invention will be described.

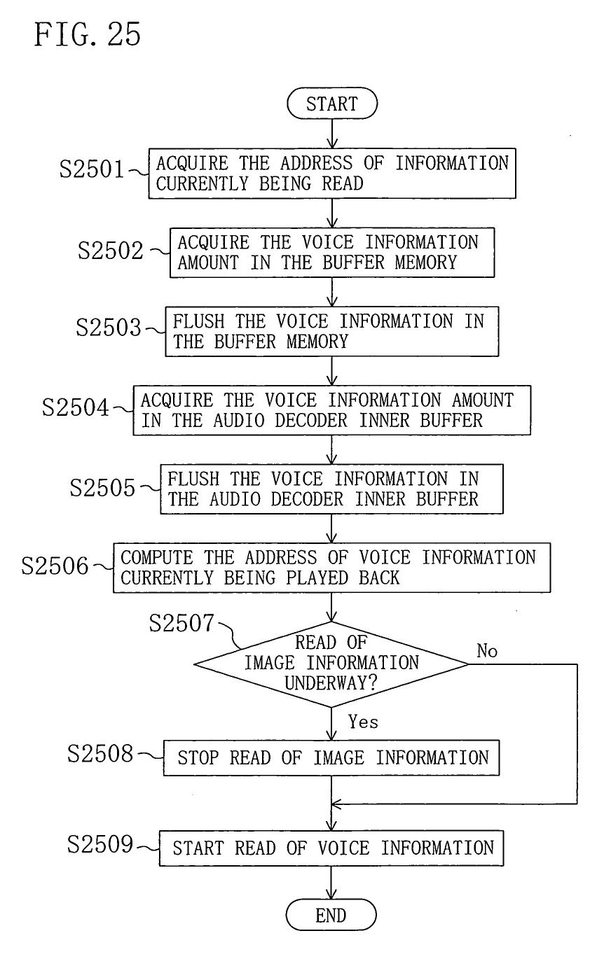

FIG. 25 is a flowchart of buffer flush processing in the information playback method of this embodiment.

In flushing of data in the audio decoder inner buffer 8 during voice playback, first, in step S2501, an address X1 on the optical disk 1 of voice information currently being read from the optical disk 1 to the buffer memory 5 is acquired. In step S2502, a current voice information amount D7 in the buffer memory 5 is acquired. In step S2503, the voice information in the buffer memory 5 is flushed.

Subsequently, in step S2504, the current voice information amount D8 in the audio decoder inner buffer 8 is acquired. In step S2505, the voice information in the audio decoder inner buffer 8 is flushed. In step S2506, an address Y1 on the optical disk 1 of voice information currently being played back is computed from the address X1 acquired in the step S2501, the voice information amount D7 acquired in the step S2502 and the voice information amount D8 acquired in the step S2504.

Thereafter, in step S2507, whether or not read of image information is underway is determined. If read of image information from the optical disk 1 to the buffer memory 5 is underway (Yes), the read of image information is stopped in step S2508. Subsequently, in step S2509, read of voice information is started from the address Y1 on the optical disk 1 of voice information currently being played back, computed in the step S2506. The processing is then terminated. If read of image information is not underway (No) in the step S2507, the process proceeds to the step S2509, skipping the step S2508, to start read of voice information from the address Y1 on the optical disk 1 of voice information currently being played back, and then the buffer flush processing is terminated.

For example, when flushing of data in the audio decoder inner buffer 8 is necessary for re-configuration of the audio decoder 7, the address X1, on the optical disk 1, of voice information currently being read from the optical disk 1 to the buffer memory 5 is first acquired. Assume that the address X1 acquired is 1234. The voice information amount D7 in the buffer memory 5 is acquired, and then voice information in the buffer memory 5 is flushed. Assume that the voice information amount D7 acquired is 23520 bytes. Subsequently, the voice information amount D8 in the audio decoder inner buffer 8 is acquired, and then voice information in the audio decoder inner buffer 8 is flushed. Assume that the voice information amount D8 acquired is 352800 bytes. When the recording medium is a CD-R, an address is given to information on the optical disk 1 for each frame, and the voice information amount of each frame is 2352 bytes. The total of the information amounts D7 and D8 is 376320 bytes. Therefore, at the time of flushing, the audio decoder 8 was playing back voice 160 frames behind the frame that was being read at the flushing. If read is restarted from the frame that was being read at the flushing, voice information will be read 160 frames ahead the frame of which voice was actually being played back at the flushing. As a result, voice of 160 frames will drop. In a CD, it takes one second to play back information of 75 frames. If the voice information under playback is MP3 data compressed to one tenth, a dropout of 21 seconds will occur. By restarting read from the frame of which voice was being played back at the flushing, such occurrence of a dropout can be prevented.

As described above, in flushing of data in the audio decoder inner buffer 8, the address on the recording medium of voice information currently being played back is computed from the address on the recording medium of voice information currently being read, the voice information amount in the buffer memory 5 and the voice information amount in the audio decoder inner buffer 8, and read is restarted from the calculated address. By adopting this method, occurrence of a dropout can be prevented.

While the present invention has been described in preferred embodiments, it will be apparent to those skilled in the art that the disclosed invention may be modified in numerous ways and may assume many embodiments other than that specifically set out and described above. Accordingly, it is intended by the appended claims to cover all modifications of the invention which fall within the true spirit and scope of the invention.

1. An information playback method for reading voice information and image information from a recording medium to a buffer memory, the voice information and the image information being recorded in the recording medium in a non-multiplexed state, supplying the read voice information to a buffer in an audio decoder and the read image information to a buffer in a video decoder, and generating an audio signal in the audio decoder and a video signal in the video decoder, to enable playback of voice and images, the method comprising the steps of:
stopping read of voice information from the recording medium to the buffer memory only when the voice information amount in the buffer memory is equal to or more than a predetermined amount that is large enough to prevent occurrence of underflow in the buffer memory, in the case of attempting simultaneous read of voice information and image information from the recording medium to the buffer memory; and
starting read of voice information from the recording medium to the buffer memory, subsequent to stopping read of image information from the recording medium to the buffer memory, only when the voice information amount in the buffer memory becomes less than the predetermined amount due to supply of voice information from the buffer memory to the audio decoder inner buffer after the step of stopping read of voice information.

2. An information playback method for reading voice information and image information from a recording medium to a buffer memory, the voice information and the image information being recorded in the recording medium in a non-multiplexed state, supplying the read voice information to a buffer in an audio decoder and the read image information to a buffer in a video decoder, and generating an audio signal in the audio decoder and a video signal in the video decoder, to enable playback of voice and images, the method comprising the steps of:
stopping read of voice information from the recording medium to the buffer memory only when the voice information amount in the buffer memory is equal to or more than a predetermined amount that is large enough to prevent occurrence of underflow in the buffer memory, in the case of attempting simultaneous read of voice information and image information from the recording medium to the buffer memory; and
starting read of voice information from the recording medium to the buffer memory, subsequent to stopping read of image information from the recording medium to the buffer memory, only when the voice information amount in the buffer memory becomes less than a second predetermined amount that is smaller than the predetermined amount and is large enough to prevent occurrence of underflow due to supply of voice information from the buffer memory to the audio decoder inner buffer after the step of stopping read of voice information.

3. The information playback method of claim 1 or 2, wherein the processing of supplying the read voice information from the buffer memory to the audio decoder inner buffer comprises the steps of:
computing the free space of the audio decoder inner buffer; and
supplying voice information of an amount smaller than the free space computed in the step of computing the free space of the audio decoder inner buffer, from the buffer memory to the audio decoder inner buffer, and
the processing of supplying the read image information from the buffer memory to the video decoder inner buffer comprises the steps of:
computing the free space of the video decoder inner buffer; and
supplying image information of an amount smaller than the free space computed in the step of computing the free space of the video decoder inner buffer, from the buffer memory to the video decoder inner buffer.

4. The information playback method of claim 1 or 2, wherein the processing of supplying the read image information from the buffer memory to the video decoder inner buffer is executed only when the voice information amount in the audio decoder inner buffer is equal to or more than a predetermined amount that is large enough to prevent occurrence of underflow.

5. The information playback method of claim 1 or 2, wherein the processing of supplying the read image information from the buffer memory to the video decoder inner buffer comprises the steps of:
computing the free space of the video decoder inner buffer; and
supplying image information from the buffer memory to the video decoder inner buffer only when the free space of the video decoder inner buffer computed in the step of computing the free space of the video decoder inner buffer is larger than a predetermined image information transfer unit.

6. The information playback method of claim 2, wherein the step of starting read of voice information comprises the steps of:
acquiring a voice information transfer rate at which voice information is transferred from the buffer memory to the audio decoder inner buffer;
computing the voice information read pre-start time required from the time of stop of read of image information from the recording medium to the buffer memory until the time of start of read of voice information from the recording medium to the buffer memory;
computing the minimum voice information amount supplied from the buffer memory to the audio decoder inner buffer during the read pre-start time based on the voice information transfer rate and the read pre-start time; and
restarting read of voice information from the recording medium to the buffer memory only when the voice information amount in the buffer memory is smaller than the minimum voice information amount.

7. The information playback method of claim 1 or 2, wherein the processing of reading image information from the recording medium to the buffer memory comprises reading in advance next image information from the recording medium to the buffer memory after termination of current image playback in the case of repeating image playback, and
the processing of supplying image information from the buffer memory to the video decoder inner buffer comprises supplying the next image information read in advance from the buffer memory to the video decoder inner buffer when start of next image playback is requested.

8. An information playback method for reading voice information and image information from a recording medium to a buffer memory, the voice information and the image information being recorded in the recording medium in a non-multiplexed state, supplying the read voice information to a buffer in an audio decoder and the read image information to a buffer in a video decoder, and generating an audio signal in the audio decoder and a video signal in the video decoder, to enable playback of voice and images, the method comprising the steps of:
stopping read of voice information from the recording medium to the buffer memory only when the voice information amount in the audio decoder inner buffer is equal to or more than a predetermined amount that is large enough to prevent occurrence of underflow in the audio decoder inner buffer, in the case of attempting simultaneous read of voice information and image information from the recording medium to the buffer memory; and
starting read of voice information from the recording medium to the buffer memory, subsequent to stopping read of image information from the recording medium to the buffer memory, only when the voice information amount in the audio decoder inner buffer becomes less than a second predetermined amount that is smaller than the predetermined amount and large enough to prevent occurrence of underflow in the audio decoder inner buffer due to playback of voice after the step of stopping read of voice information.

9. An information playback method for reading voice information and image information from a recording medium to a buffer memory, the voice information and the image information being recorded in the recording medium in a non-multiplexed state, supplying the read voice information to a buffer in an audio decoder and the read image information to a buffer in a video decoder, and generating an audio signal in the audio decoder and a video signal in the video decoder, to enable playback of voice and images, the method comprising the steps of:
stopping read of voice information from the recording medium to the buffer memory only when the voice information amount in the buffer memory exceeds the free space of the audio decoder inner buffer, in the case of attempting simultaneous read of voice information and image information from the recording medium to the buffer memory; and
starting read of voice information from the recording medium to the buffer memory, subsequent to stopping read of image information from the recording medium to the buffer memory, only when the image information amount in the buffer memory exceeds the free space of the video decoder inner buffer or when the voice information amount in the audio decoder inner buffer becomes less than a predetermined amount that is large enough to prevent occurrence of underflow due to playback of voice after the step of stopping read of voice information.

10. The method of any of claims 1, 2, 6, 8 or 9, further comprising the steps of:
acquiring the voice information amount in the buffer memory;
flushing the voice information in the buffer memory;
acquiring the voice information amount in the audio decoder inner buffer;
flushing the voice information in the audio decoder inner buffer;
acquiring an address on the recording medium of voice information currently being read at the flushing of the voice information in the audio decoder inner buffer;
computing an address on the recording medium of voice information currently being played back based on the acquired address on the recording medium of the voice information currently being read, the acquired voice information amount in the buffer memory and the acquired voice information amount in the audio decoder inner buffer; and
restarting read of voice information from the address on the recording medium of the voice information currently being played back computed in the step of computing an address.
